(19) United States
(12) Patent Application Publication
(10) Pub. No.: US 2025/0365123 A1
(43) Pub. Date: Nov. 27, 2025

(54) SEMICONDUCTOR DEVICE AND SEMICONDUCTOR SYSTEM PERFORMING SIMULTANEOUS BI-DIRECTIONAL COMMUNICATION

(71) Applicant: SK hynix Inc., Icheon-si Gyeonggi-do (KR)

(72) Inventors: Min Chang KIM, Icheon-si Gyeonggi-do (KR); Soon Chul KWON, Icheon-si Gyeonggi-do (KR); Seul Gi KIM, Icheon-si Gyeonggi-do (KR); Ic Su OH, Icheon-si Gyeonggi-do (KR); Han Kyu CHI, Icheon-si Gyeonggi-do (KR)

(73) Assignee: SK hynix Inc., Icheon-si Gyeonggi-do (KR)

(21) Appl. No.: 18/903,534

(22) Filed: Oct. 1, 2024

(30) Foreign Application Priority Data
May 24, 2024 (KR) 10-2024-0067740

(51) Int. Cl. H04L 5/14; H04L 25/03

(52) U.S. Cl. CPC H04L 5/1461; H04L 25/03038

(57) ABSTRACT

A semiconductor device includes a serializer, a transmission circuit, and a reception circuit. The serializer is configured to generate transmission data from first and second output data signals based on first and second transmission clock signals. The transmission circuit is configured to drive, based on the transmission data, a node that is electrically coupled to a signal transmission line. The reception circuit is configured to generate reception data, based on the first and second reception clock signals, the first and second output data signals, and a voltage level of the node.

### CROSS-REFERENCES TO RELATED APPLICATION

The present application claims priority under 35 U.S.C. § 119(a) to Korean Patent Application No. 10-2024-0067740, filed in the Korean Intellectual Property Office on May 24, 2024, the entire contents of which application is incorporated herein by reference.

### BACKGROUND

### 1. Technical Field

Various embodiments relate to an integrated circuit technology, and more particularly, to a semiconductor device and a semiconductor system which perform simultaneous bi-directional communication.

### 2. Related Art

An electronic device includes many electronic components, and may include many semiconductor devices consisting of computer system semiconductors, among the electronic components. Semiconductor devices that constitute a computer system may communicate with each other by transmitting and receiving clocks and data. Semiconductor devices having higher bandwidths are being developed so that the semiconductor devices can rapidly process a larger amount of data. The easiest method of increasing the bandwidth of the semiconductor device is to increase the number of input and output pins through which data are input and output. However, the number of input and output pins which may be increased is limited due to the limitation of a physical space of a semiconductor package. To increase the bandwidth of the semiconductor device without increasing the number of input and output pins, there is a method of increasing the data rate. However, increasing the data rate might not be suitable for a semiconductor device and a semiconductor system that currently operate at a high speed because inter-symbol interference (ISI) is increased due to a channel loss.

Accordingly, to increase the bandwidth of the semiconductor device without increasing the number of input and output pins and the data rate, a simultaneous bi-directional (SBD) communication method has been developed. The SBD communication method may be a method of superposing a first transmission signal that is transmitted from a first semiconductor device to a second semiconductor device and a second transmission signal that is transmitted from the second semiconductor device to the first semiconductor device on one signal transmission line. The voltage level of the second transmission signal may be superposed onto the voltage level of the first transmission signal at a node of the first semiconductor device. The first semiconductor device may receive the second transmission signal as a first reception signal by subtracting the voltage level of the first transmission signal from the voltage level of a superposition signal of the node. Likewise, the voltage level of the first transmission signal may be superposed onto the voltage level of the second transmission signal at a node of the second semiconductor device. The second semiconductor device may receive the first transmission signal as a second reception signal by subtracting the voltage level of the second transmission signal from the voltage level of a superposition signal of the node. However, the SBD communication method can result in signal distortion.

### SUMMARY

A semiconductor device in accordance with an embodiment may include a serializer, a transmission circuit, and a reception circuit. The serializer may be configured to generate transmission data by serializing a first output data signal and a second output data signal based on a first transmission clock signal and a second transmission clock signal. The transmission circuit may be configured to drive, based on the transmission data, a node that is electrically coupled to a signal transmission line. The reception circuit may be configured to generate, based on a first reception clock signal, a second reception clock signal, the first output data signal, and the second output data signal, reception data by detecting a voltage level of the node.

A semiconductor device in accordance with an embodiment may include a serializer, a delay circuit, a transmission circuit, and a reception circuit. The serializer may be configured to generate transmission data by serializing a first output data signal, a second output data signal, a third output data signal, and a fourth output data signal, based on a first transmission clock signal, a second transmission clock signal, a third transmission clock signal, and a fourth transmission clock signal having different phases. The delay circuit may be configured to generate a first delay data signal, a second delay data signal, a third delay data signal, and a fourth delay data signal by delaying the first, second, third, and fourth output data signals, respectively. The transmission circuit may be configured to drive, based on the transmission data, a node that is electrically coupled to a signal transmission line. The reception circuit may be configured to generate reception data by detecting a voltage level of the node, based on a first reception clock signal, a second reception clock signal, a third reception clock signal, and a fourth reception clock signal, and the first, second, third, and fourth delay data signals.

A semiconductor device in accordance with an embodiment may include a serializer, a transmission circuit, a delay setting circuit, and a reception circuit. The serializer may be configured to generate transmission data by serializing a first output data signal and a second output data signal based on a first transmission clock signal and a second transmission clock signal. The transmission circuit may be configured to drive a node based on the transmission data. The delay setting circuit may be electrically coupled between the node and a signal transmission line, wherein a delay time duration of the delay setting circuit may be set based on a voltage level of the node. The reception circuit may be configured to generate reception data based on the voltage level of the node, a first reception clock signal, a second reception clock signal, the first output data signal, and the second output data signal.

### BRIEF DESCRIPTION OF THE DRAWINGS

FIG. 1 is a diagram illustrating a configuration of a semiconductor system according to an embodiment.

FIG. 2A is a timing diagram illustrating an operation of the semiconductor system illustrated in FIG. 1.

FIG. 2B is a timing diagram illustrating another operation of a first semiconductor device illustrated in FIG. 1

FIG. 3 is a diagram illustrating a configuration of a semiconductor system according to an embodiment.

FIG. 4 is a timing diagram illustrating an operation of the first semiconductor device illustrated in FIG. 3.

FIG. 5 is a diagram illustrating a configuration of a semiconductor device according to an embodiment.

FIG. 6 is a timing diagram illustrating an overall operation of the semiconductor device according to an embodiment.

FIG. 7A is a timing diagram illustrating an operation of the first semiconductor device illustrated in FIG. 3.

FIG. 7B is a timing diagram illustrating an operation of the semiconductor device illustrated in FIG. 5.

FIG. 8 is a diagram illustrating a configuration of a semiconductor device according to an embodiment.

FIG. 9 is a diagram illustrating a configuration of a delay setting circuit illustrated in FIG. 8.

FIG. 10A is a timing diagram illustrating an operation of a semiconductor device that does not include the delay setting circuit illustrated in FIG. 8, and FIG. 10B is a timing diagram illustrating an operation of the semiconductor device illustrated in FIG. 8.

FIG. 11 is a diagram illustrating a configuration of a semiconductor device according to an embodiment.

FIG. 12 is a timing diagram illustrating an operation of the semiconductor device illustrated in FIG. 11.

FIG. 13 is a diagram illustrating a configuration of a semiconductor device according to an embodiment.

FIG. 14 is a diagram illustrating a configuration of a semiconductor device according to an embodiment.

FIG. 15 is a diagram illustrating a configuration and connection relation of a sampling circuit and a selection circuit which are illustrated in FIG. 14.

FIG. 16 is a timing diagram illustrating an operation of a semiconductor device according to an embodiment.

### DETAILED DESCRIPTION

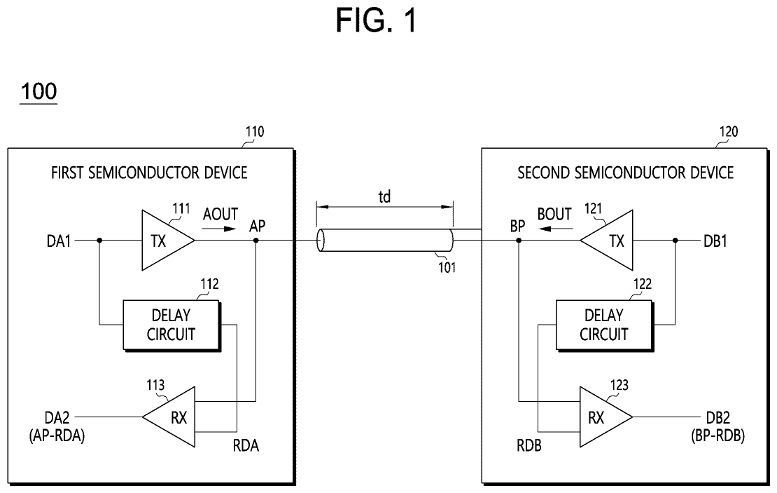

FIG. 1 is a diagram illustrating a configuration of a semiconductor system 100 according to an embodiment. Referring to FIG. 1, the semiconductor system 100 may include a first semiconductor device 110 and a second semiconductor device 120. The first and second semiconductor devices 110 and 120 may communicate with each other by being electrically coupled through a signal transmission line 101. The first and second semiconductor devices 110 and 120 may perform simultaneous bi-directional (SBD) communication. The first semiconductor device 110 may transmit an internal signal of the first semiconductor device 110 to the second semiconductor device 120 through the signal transmission line 101. The second semiconductor device 120 may transmit an internal signal of the second semiconductor device 120 to the first semiconductor device 110 through the signal transmission line 101. In an interval that is superposed onto an interval in which the first semiconductor device 110 transmits the internal signal of the first semiconductor device 110 through the signal transmission line 101, the second semiconductor device 120 may transmit the internal signal of the second semiconductor device 120 to the first semiconductor device 110. While the first semiconductor device 110 is transmitting a signal through the signal transmission line 101 to the second semiconductor device 120, the second semiconductor device 120 may also be transmitting a signal through the signal transmission line 101 to the first semiconductor device 110. In an embodiment, the internal signals of the first and second semiconductor devices 110 and 120 may be data. A signal that is transmitted by the first semiconductor device 110 and a signal that is transmitted by the second semiconductor device 120 may be superposed on the signal transmission line 101. The first semiconductor device 110 may be electrically coupled to the signal transmission line 101 through a first node AP. The second semiconductor device 120 may be electrically coupled to the signal transmission line 101 through a second node BP. The first semiconductor device 110 may drive the first node AP based on first transmission data DA1. A signal that is transmitted by the second semiconductor device 120 may be superposed at the first node AP. The first semiconductor device 110 may receive the signal transmitted by the second semiconductor device 120, by subtracting the voltage level of the first transmission data DA1 from the voltage level of the first node AP. The second semiconductor device 120 may drive the second node BP based on second transmission data DB1. A signal that is transmitted by the first semiconductor device 110 may be superposed in the second node BP. The second semiconductor device 120 may receive the signal transmitted by the first semiconductor device 110, by subtracting the voltage level of the second transmission data DB1 from the voltage level of the second node BP.

The first semiconductor device 110 may include a transmission circuit (TX) 111, a delay circuit 112, and a reception circuit (RX) 113. The transmission circuit 111 may receive the first transmission data DA1, and may drive the first node AP based on the first transmission data DA1. The transmission circuit 111 may output, to the first node AP, a first output voltage AOUT corresponding to the first transmission data DA1. The delay circuit 112 may receive the first transmission data DA1, and may generate first delay data RDA by delaying the first transmission data DA1. The delay circuit 112 may have a delay time duration that is replicated from the propagation delay of the transmission circuit 111. The reception circuit 113 may be electrically coupled to the first node AP, and may receive the first delay data RDA from the delay circuit 112. The reception circuit 113 may generate first reception data DA2 by comparing the voltage level of the first node AP and the voltage level of the first delay data RDA. The first reception data DA2 may be at a logic level and/or voltage level corresponding to the second transmission data DB1.

The second semiconductor device 120 may include a transmission circuit (TX) 121, a delay circuit 122, and a reception circuit (RX) 123. The transmission circuit 121 may receive the second transmission data DB1, and may drive the second node BP based on the second transmission data DB1. The transmission circuit 121 may output, to the second node BP, a second output voltage BOUT corresponding to the second transmission data DB1. The delay circuit 122 may receive the second transmission data DB1, and may generate second delay data RDB by delaying the second transmission data DB1. The delay circuit 122 may have a delay time duration that is replicated from the propagation delay of the transmission circuit 121. The reception circuit 123 may be electrically coupled to the second node BP, and may receive the second delay data RDB from the delay circuit 122. The reception circuit 123 may generate second reception data DB2 by comparing the voltage level of the second node BP and the voltage level of the second delay data RDB. The second reception data DB2 may be at a logic level and/or voltage level corresponding to the first transmission data DA1.

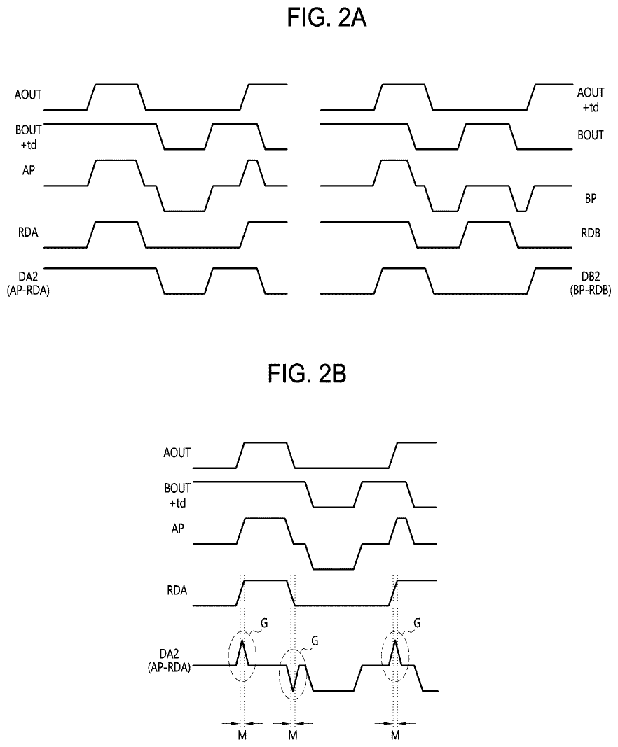

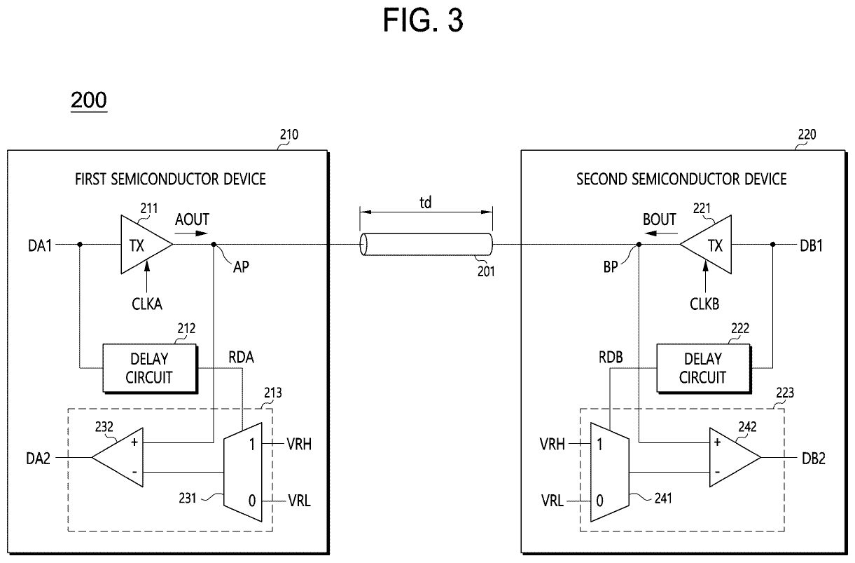

FIG. 2A is a timing diagram illustrating an operation of the semiconductor system 100 illustrated in FIG. 1. An operation of the semiconductor system 100 according to an embodiment is described as follows with reference to FIGS. 1 and 2A. The transmission circuit 111 of the first semiconductor device 110 may output the first output voltage AOUT to the first node AP based on the first transmission data DA1. Simultaneously, the transmission circuit 121 of the second semiconductor device 120 may output the second output voltage BOUT to the second node BP based on the second transmission data DB1. The second output voltage BOUT may be transmitted to the first semiconductor device 110 through the signal transmission line 101. The first output voltage AOUT and the second output voltage BOUT may be superposed in the first node AP. The phase of the second output voltage BOUT may be delayed by a delay time duration “td” of the signal transmission line 101 because the second output voltage BOUT is transmitted through the signal transmission line 101. In FIG. 2A, a second output voltage that is delayed through the signal transmission line 101 is indicated as “BOUT+td”. The delay circuit 112 may generate the first delay data RDA by delaying the first transmission data DA1. When the delay time duration of the delay circuit 112 and the propagation delay of the transmission circuit 111 are accurately matched, the first delay data RDA may have substantially the same voltage level as the first output voltage AOUT. The reception circuit 113 may generate the first reception data DA2 (AP-RDA) by subtracting the voltage level of the first delay data RDA from the voltage level of the first node AP. Accordingly, the voltage level of the first reception data DA2 that are generated by the reception circuit 113 may be substantially the same as the voltage level of the second output voltage “BOUT+td”.

The first output voltage AOUT may be transmitted to the second semiconductor device 120 through the signal transmission line 101. The first output voltage AOUT and the second output voltage BOUT may be superposed in the second node BP. The phase of the first output voltage AOUT may be delayed by the delay time duration of the signal transmission line 101 because the first output voltage AOUT is transmitted through the signal transmission line 101. In FIG. 2A, a first output voltage that is delayed through the signal transmission line 101 is indicated as “AOUT+td”. The delay circuit 122 may generate the second delay data RDB by delaying the second transmission data DB1. When the delay time duration of the delay circuit 122 and the propagation delay of the transmission circuit 121 are accurately matched, the second delay data RDB may have substantially the same voltage level as the second output voltage BOUT. The reception circuit 123 may generate the second reception data DB2 (BP-BOUT) by subtracting the voltage level of the second delay data RDB from the voltage level of the second node BP. Accordingly, the voltage level of the second reception data DB2 (BP-RDB) that is generated by the reception circuit 123 may be substantially the same as the voltage level of the first output voltage AOUT.

FIG. 2B is a timing diagram illustrating another operation of the first semiconductor device 110 illustrated in FIG. 1. Referring to FIGS. 1 and 2B, when the delay circuit 112 accurately replicates the propagation delay of the transmission circuit 111, as illustrated in FIG. 2A, the reception circuit 113 may generate the first reception data DA2 that accurately corresponds to the second output voltage BOUT, from the voltage level of the first node AP. However, there may be a good possibility that a mismatch will occur between the delay time duration of the delay circuit 112 and the propagation delay of the transmission circuit 111 due to various factors, such as a process variation, and channel environment in which semiconductor devices are electrically coupled through the signal transmission line. The reason for this is that the delay circuit 112 needs to consider a load of the signal transmission line 101 itself and loads of the transmission circuit 121 and reception circuit 123 of the second semiconductor device 120 that is electrically coupled to the signal transmission line 101, in addition to the propagation delay of the transmission circuit 111. For this reason, it may be very difficult to generate the first delay data RDA having substantially the same phase as the first output voltage AOUT through the delay circuit 112. As illustrated in FIG. 2B, when a mismatch M in which the phase of the first delay data RDA is later than the phase of the first output voltage AOUT occurs, distortion may occur in the voltage level of the first reception data DA2 because an unexpected glitch G occurs in the voltage level of the first reception data DA2. If the first reception data DA2 does not correspond to the second output voltage BOUT and/or the second transmission data DB1, the semiconductor system 100 may not be able to perform accurate data communication.

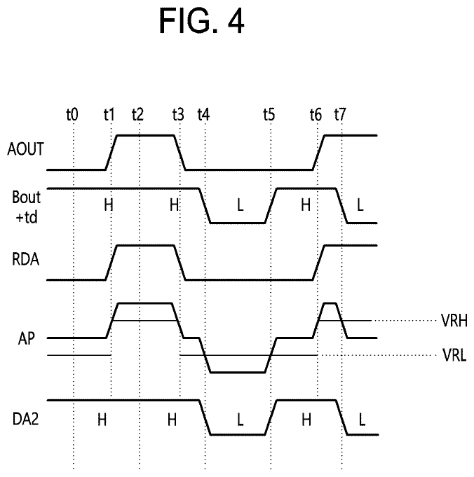

FIG. 3 is a diagram illustrating a configuration of a semiconductor system 200 according to an embodiment. Referring to FIG. 3, the semiconductor system 200 may include a first semiconductor device 210 and a second semiconductor device 220. The first and second semiconductor devices 210 and 220 may be electrically coupled through a signal transmission line 201. The first semiconductor device 210 may include a transmission circuit (TX) 211, a delay circuit 212, and a reception circuit 213. The transmission circuit 211 may receive first transmission data DA1, and may drive a first node AP based on the first transmission data DA1. The transmission circuit 211 may output, to the first node AP, first output voltage AOUT corresponding to the first transmission data DA1. The delay circuit 212 may receive the first transmission data DA1, and may generate first delay data RDA by delaying the first transmission data DA1. The delay circuit 212 may have a delay time duration that is replicated from the propagation delay of the transmission circuit 211. The reception circuit 213 may be electrically coupled to the first node AP, and may receive the first delay data RDA from the delay circuit 212. The reception circuit 213 may receive a first reference voltage VRH and a second reference voltage VRL. The first reference voltage VRH may have a higher voltage level than the second reference voltage VRL. For example, the voltage level of the first node AP may be changed to be between a high boundary voltage level and a low boundary voltage level. A middle voltage level may be a voltage level corresponding to an average of the high boundary voltage level and the low boundary voltage level. The first reference voltage VRH may have a voltage level between the high boundary voltage level and the middle voltage level. The second reference voltage VRL may have a voltage level between the middle voltage level and the low boundary voltage level. The reception circuit 213 may select one of the first reference voltage VRH and the second reference voltage VRL, based on the first delay data RDA. The reception circuit 213 may generate first reception data DA2 by comparing the voltage level of the first node AP and the selected reference voltage. The reception circuit 213 may include a voltage selection circuit 231 and a comparator 232. The voltage selection circuit 231 may receive the first delay data RDA, and may output one of the first and second reference voltages VRH and VRL based on the logic level of the first delay data RDA. For example, when the first delay data RDA are at a logic low level, the voltage selection circuit 231 may output the second reference voltage VRL. When the first delay data RDA are at a logic high level, the voltage selection circuit 231 may output the first reference voltage VRH. The comparator 232 may generate the first reception data DA2 by comparing the voltage level of the first node AP and a reference voltage that is output by the voltage selection circuit 231.

The second semiconductor device 220 may include a transmission circuit (TX) 221, a delay circuit 222, and a reception circuit 223. The transmission circuit 221 may receive second transmission data DB1, and may drive a second node BP based on the second transmission data DB1. The transmission circuit 221 may output, to the second node BP, a second output voltage BOUT corresponding to the second transmission data DB1. The delay circuit 222 may receive the second transmission data DB1, and may generate second delay data RDB by delaying the second transmission data DB1. The delay circuit 222 may have a delay time duration that is replicated from the propagation delay of the transmission circuit 221. The reception circuit 223 may be electrically coupled to the second node BP, and may receive the second delay data RDB from the delay circuit 222. The reception circuit 223 may receive the first reference voltage VRH and the second reference voltage VRL. The reception circuit 223 may select one of the first reference voltage VRH and the second reference voltage VRL, based on the second delay data RDB. The reception circuit 223 may generate second reception data DB2 by comparing the voltage level of the second node BP and the selected reference voltage. The reception circuit 223 may include a voltage selection circuit 241 and a comparator 242. The voltage selection circuit 241 may receive the second delay data RDB, and may output one of the first and second reference voltages VRH and VRL based on the logic level of the second delay data RDB. For example, when the second delay data RDB are at a logic low level, the voltage selection circuit 241 may output the second reference voltage VRL. When the second delay data RDB are at a logic high level, the voltage selection circuit 241 may output the first reference voltage VRH. The comparator 242 may generate the second reception data DB2 by comparing the voltage level of the second node BP and a reference voltage that is output by the voltage selection circuit 241.

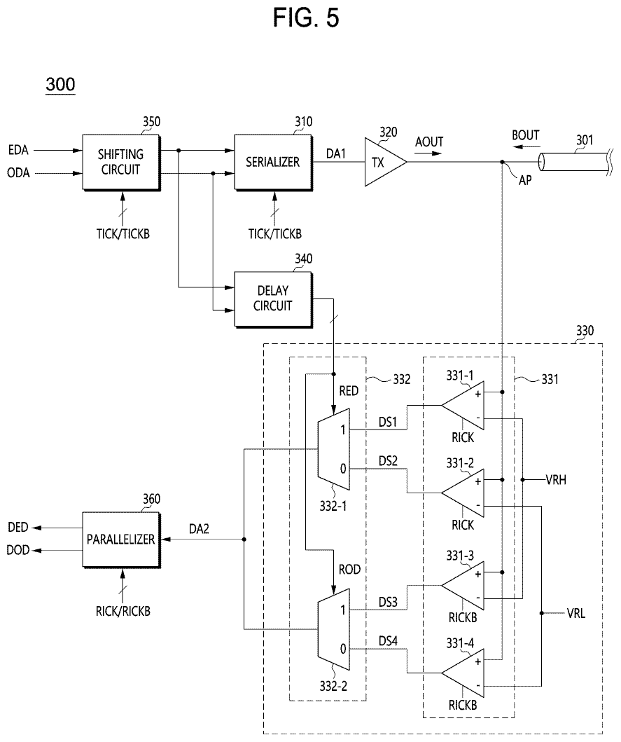

FIG. 4 is a timing diagram illustrating an operation of the first semiconductor device 210 illustrated in FIG. 3. Referring to FIGS. 3 and 4, the transmission circuit 211 of the first semiconductor device 210 may output the first output voltage AOUT to the first node AP based on the first transmission data DA1. Simultaneously, the transmission circuit 221 of the second semiconductor device 220 may output the second output voltage BOUT to the second node BP based on the second transmission data DB1. The second output voltage BOUT may be transmitted through the signal transmission line 201, and may be superposed onto the first output voltage AOUT at the first node AP. The second output voltage BOUT may have a phase that is delayed by a delay time duration “td” of the signal transmission line 201. In FIG. 3, a second output voltage that is delayed by the delay time duration “td” of the signal transmission line 201 is indicated as “BOUT+td”. At time to, when the delay data RDA are at a logic low level, the voltage selection circuit 231 may output the second reference voltage VRL. The comparator 232 may output a first bit of the first reception data DA2 by comparing the voltage level of the first node AP and the voltage level of the second reference voltage VRL. In an interval between times to and t1, the first bit of the first reception data DA2 may be at a logic high level because the first node AP has a higher voltage level than the second reference voltage VRL. At time t1, the logic level of the first delay data RDA may transition to a logic high level, and the voltage selection circuit 231 may output the first reference voltage VRH. The comparator 232 may output a second bit of the first reception data DA2 by comparing the voltage level of the first node AP and the voltage level of the first reference voltage VRH. In an interval between times t1 and t2, the first bit of the first reception data DA2 may be maintained at the logic high level because the first node AP has a higher voltage level than the first reference voltage VRH. In an interval between times t2 and t3, the second bit of the first reception data DA2 may be at a logic high level because the first node AP has a higher voltage level than the first reference voltage VRH. At time t3, the logic level of the first delay data RDA may transition to a logic low level, and the voltage selection circuit 231 may output the second reference voltage VRL. In an interval between times t3 and t4, the comparator 232 may maintain the logic level of the second bit of the first reception data DA2 at the logic high level by comparing the voltage level of the first node AP and the voltage level of the second reference voltage VRL. In an interval between times t4 and t5, a third bit of the first reception data DA2 may be at a logic low level because the first node AP has a lower voltage level than the second reference voltage VRL. At time t5, the first delay data RDA may be maintained at the logic low level, and the voltage selection circuit 231 may continue to output the second reference voltage VRL. The comparator 232 may generate a fourth bit of the first reception data DA2 by comparing the voltage level of the first node AP and the voltage level of the second reference voltage VRL. In an interval between times t5 and t6, the fourth bit of the first reception data DA2 may be at a logic high level because the first node AP has a higher voltage level than the second reference voltage VRL. At time t6, the logic level of the first delay data RDA may transition to a logic high level, and the voltage selection circuit 231 may output the first reference voltage VRH. In an interval between times t6 and t7, the comparator 232 may maintain the fourth bit of the first reception data DA2 at the logic high level by comparing the voltage level of the first node AP and the voltage level of the first reference voltage VRH. After time t7, a fifth bit of the first reception data DA2 may be at a logic low level because the first node AP has a lower voltage level than the first reference voltage VRH.

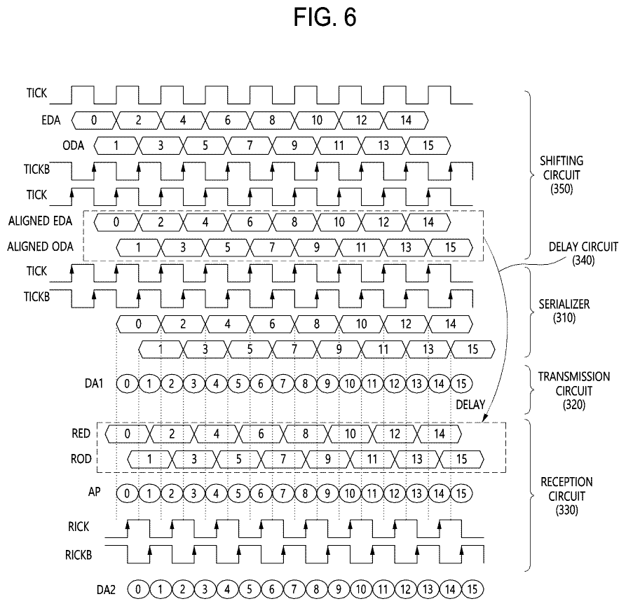

FIG. 5 is a diagram illustrating a configuration of a semiconductor device 300 according to an embodiment. Referring to FIG. 5, the semiconductor device 300 may be electrically coupled to a signal transmission line 301, and may be electrically coupled to another semiconductor device through the signal transmission line 301. For example, the semiconductor device 300 may correspond to the first semiconductor device 110 or 210 illustrated in FIG. 1 or 3. The other semiconductor device may correspond to the second semiconductor device 120 or 220 illustrated in FIG. 1 or 3. The semiconductor device 300 may include a serializer 310, a transmission circuit (TX) 320, and a reception circuit 330. The serializer 310 may generate transmission data DA1 by receiving a first output data signal EDA, a second output data signal ODA, a first transmission clock signal TICK, and a second transmission clock signal TICKB. The serializer 310 may generate the transmission data DA1 by serializing the first and second output data signals EDA and ODA based on the first and second transmission clock signals TICK and TICKB. The first and second output data signals EDA and ODA may each be parallel data. The transmission data DA1 may be serial data. The duration of each of the first and second output data signals EDA and ODA may be longer than the duration of each of bits of the transmission data DA1. The first and second transmission clock signals TICK and TICKB may each be a half-rate clock signal, and may have different phases. For example, the second transmission clock signal TICKB may have a phase that is later than the phase of the first transmission clock signal TICK by 180 degrees. In an embodiment, the first and second transmission clock signals TICK and TICKB may each be a part of a quarter-rate clock signal. A difference between the phases of the first and second transmission clock signals TICK and TICKB may be 90 degrees. The serializer 310 may output the first output data signal EDA as the transmission data DA1 in synchronization with the first transmission clock signal TICK, and may output the second output data signal ODA as the transmission data DA1 in synchronization with the second transmission clock signal TICKB. For example, the serializer 310 may change the logic level of the transmission data DA1 based on the logic level of the first output data signal EDA at a rising edge of the first transmission clock signal TICK. The serializer 310 may change the logic level of the transmission data DA1 based on the logic level of the second output data signal ODA at a rising edge of the second transmission clock signal TICKB.

The transmission circuit 320 may receive the transmission data DA1, and may drive a node AP based on the transmission data DA1. The node AP may be electrically coupled to the signal transmission line 301. The transmission circuit 320 may output, to the node AP, an output voltage AOUT corresponding to the transmission data DA1. An output voltage BOUT may be transmitted by the other semiconductor device through the signal transmission line 301. The output voltage AOUT and the output voltage BOUT transmitted by the other semiconductor device may be superposed at the node AP. The node AP may be at the superposed voltage level.

The reception circuit 330 may generate reception data DA2 by detecting the voltage level of the node AP, based on the first output data signal EDA, the second output data signal ODA, a first reception clock signal RICK, and a second reception clock signal RICKB. The first and second reception clock signals RICK and RICKB may each have substantially the same cycle as the first and second transmission clock signals TICK and TICKB. In an embodiment, the first and second reception clock signals RICK and RICKB and the first and second transmission clock signals TICK and TICKB may be generated from the same clock source. In an embodiment, the first and second reception clock signals RICK and RICKB may have the same phases as the first and second transmission clock signals TICK and TICKB, respectively. In an embodiment, the first and second reception clock signals RICK and RICKB may each have a phase that is later than that of each of the first and second transmission clock signals TICK and TICKB, respectively, by a quarter (¼) of a cycle. For example, the first reception clock signal RICK may have a phase that is later than that of the first transmission clock signal TICK by 90 degrees. The second reception clock signal RICKB may have a phase that is later than that of the second transmission clock signal TICKB by 90 degrees. The reception circuit 330 may receive a first delay data signal RED and a second delay data signal ROD. The first delay data signal RED may be generated by delaying the first output data signal EDA. The second delay data signal ROD may be generated by delaying the second output data signal ODA. The semiconductor device 300 may further include a delay circuit 340. The delay circuit 340 may receive the first and second output data signals EDA and ODA, and may generate the first and second delay data signals RED and ROD by delaying the first and second output data signals EDA and ODA, respectively. The delay circuit 340 may have a delay time duration that is replicated from the propagation delay of the serializer 310 and the transmission circuit 320. The reception circuit 330 may receive a first reference voltage VRH and a second reference voltage VRL to detect the voltage level of the node AP. The first reference voltage VRH may have a voltage level between a high boundary voltage level and middle voltage level of the node AP. The second reference voltage VRL may have a voltage level between the middle voltage level and low boundary voltage level of the node AP. When the first reception clock signal RICK is at a logic high level, the reception circuit 330 may generate two sampled signals by sampling the voltage level of the node AP by using the first and second reference voltages VRH and VRL, and may provide one of the two sampled signals as the reception data DA2 based on the first delay data signal RED. When the second reception clock signal RICKB is at a logic high level, the reception circuit 330 may generate two sampled signals by sampling the voltage level of the node AP by using the first and second reference voltages VRH and VRL, and may provide one of the two sampled signals as the reception data DA2 based on the second delay data signal ROD.

The reception circuit 330 may include a sampling circuit 331 and a selection circuit 332. The sampling circuit 331 may generate a first detection signal DS1 and a second detection signal DS2 by comparing the voltage level of the node AP with each of the first and second reference voltages VRH and VRL in synchronization with the first reception clock signal RICK. The sampling circuit 331 may generate the results of the comparison between the voltage level of the node AP and the first reference voltage VRH as the first detection signal DS1, and may generate the results of the comparison between the voltage level of the node AP and the second reference voltage VRL as the second detection signal DS2. The sampling circuit 331 may generate a third detection signal DS3 and a fourth detection signal DS4 by comparing the voltage level of the node AP with each of the first and second reference voltages VRH and VRL in synchronization with the second reception clock signal RICKB. The sampling circuit 331 may generate the results of the comparison between the voltage level of the node AP and the first reference voltage VRH as the third detection signal DS3, and may generate the results of the comparison between the voltage level of the node AP and the second reference voltage VRL as the fourth detection signal DS4.

The sampling circuit 331 may include a first comparator 331-1, a second comparator 331-2, a third comparator 331-3, and a fourth comparator 333-4. The first and second comparators 331-1 and 331-2 may receive the first reception clock signal RICK, and may be activated when the first reception clock signal RICK is at a logic high level. The third and fourth comparators 331-3 and 331-4 may receive the second reception clock signal RICKB, and may be activated when the second reception clock signal RICKB is at a logic high level. The first comparator 331-1 may receive the voltage level of the node AP and the first reference voltage VRH, and may generate the first detection signal DS1 by comparing the voltage level of the node AP and the voltage level of the first reference voltage VRH. The second comparator 331-2 may receive the voltage level of the node AP and the second reference voltage VRL, and may generate the second detection signal DS2 by comparing the voltage level of the node AP and the voltage level of the second reference voltage VRL. The third comparator 331-3 may receive the voltage level of the node AP and the first reference voltage VRH, and may generate the third detection signal DS3 by comparing the voltage level of the node AP and the voltage level of the first reference voltage VRH. The fourth comparator 331-4 may receive the voltage level of the node AP and the second reference voltage VRL, and may generate the fourth detection signal DS4 by comparing the voltage level of the node AP and the voltage level of the second reference voltage VRL. For example, the first to fourth comparators 331-1, 331-2, 331-3, and 331-4 may generate the first to fourth detection signals DS1 to DS4 each being at a logic high level, respectively, when the node AP has a higher voltage level than the first reference voltage VRH or the second reference voltage VRL. The first to fourth comparators 331-1, 331-2, 331-3, and 331-4 may generate the first to fourth detection signals DS1 to DS4 each being at a logic low level, respectively, when the node AP has a lower voltage level than the first reference voltage VRH or the second reference voltage VRL.

The selection circuit 332 may output one of the first and second detection signals DS1 and DS2 as the reception data DA2 based on the first delay data signal RED, and may output one of the third and fourth detection signals DS3 and DS4 as the reception data DA2 based on the second delay data signal ROD. The selection circuit 332 may output the first detection signal DS1 as the reception data DA2 when the first delay data signal RED is at a first logic level, and may output the second detection signal DS2 as the reception data DA2 when the first delay data signal RED is at a second logic level. For example, the first logic level may be a logic high level, and the second logic level may be a logic low level. The selection circuit 332 may output the third detection signal DS3 as the reception data DA2 when the second delay data signal ROD is at the first logic level, and may output the fourth detection signal DS4 as the reception data DA2 when the second delay data signal ROD is at the second logic level.

The selection circuit 332 may include a first multiplexer 332-1 and a second multiplexer 332-2. The first multiplexer 332-1 may receive the first delay data signal RED, the first detection signal DS1, and the second detection signal DS2. The first multiplexer 332-1 may output the first detection signal DS1 as the reception data DA2 when the first delay data signal RED is at the first logic level. The first multiplexer 332-1 may output the second detection signal DS2 as the reception data DA2 when the first delay data signal RED is at the second logic level. The second multiplexer 332-2 may receive the second delay data signal ROD, the third detection signal DS3, and the fourth detection signal DS4. The second multiplexer 332-2 may output the third detection signal DS3 as the reception data DA2 when the second delay data signal ROD is at the first logic level. The second multiplexer 332-2 may output the fourth detection signal DS4 as the reception data DA2 when the second delay data signal ROD is at the second logic level.

The semiconductor device 300 may further include a shifting circuit 350. The shifting circuit 350 may align the first and second data signals EDA and ODA and provide the aligned data signal to the serializer 310. The shifting circuit 350 may receive the first transmission clock signal TICK, the second transmission clock signal TICKB, the first output data signal EDA, and the second output data signal ODA. The shifting circuit 350 may align the first and second output data signals EDA and ODA with the phases of the first and second transmission clock signals TICK and TICKB, respectively. The shifting circuit 350 may align the first and second output data signals EDA and ODA to increase an operation margin of the serializer 310. The shifting circuit 350 may align the first and second output data signals EDA and ODA by using a clock signal having a phase that is earlier than the phase of a clock signal with which the serializer 310 is synchronized. For example, the shifting circuit 350 may align the first output data signal EDA in synchronization with the second transmission clock signal TICKB, and may align the second output data signal ODA in synchronization with the first transmission clock signal TICK. The shifting circuit 350 may provide the serializer 310 with the first and second output data signals EDA and ODA that have been aligned with the phases of the second transmission clock signal TICKB and the first transmission clock signal TICK, respectively. A setup margin for allowing the serializer 310 to sample the first output data signal EDA can be sufficiently established or secured because the serializer 310 samples the first output data signal EDA that has been aligned with the phase of the second transmission clock signal TICKB, in synchronization with the first transmission clock signal TICK. Likewise, a setup margin for allowing the serializer 310 to sample the second output data signal ODA can be sufficiently established or secured because the serializer 310 samples the second output data signal ODA that has been aligned with the phase of the first transmission clock signal TICK, in synchronization with the second transmission clock signal TICKB. When the semiconductor device 300 includes the shifting circuit 350, the delay circuit 340 may receive the first output data signal EDA and the second output data signal ODA that have been aligned by the shifting circuit 350.

The semiconductor device 300 may further include a parallelizer 360. The parallelizer 360 may receive the reception data DA2, and may generate a first input data signal DED and a second input data signal DOD by parallelizing the reception data DA2. The reception data DA2 may be serial data as is the transmission data DA1. The parallelizer 360 may receive the first and second reception clock signals RICK and RICKB. The parallelizer 360 may generate the first and second input data signals DED and DOD by parallelizing the reception data DA2 in synchronization with the first and second reception clock signals RICK and RICKB. For example, when the first reception clock signal RICK is at a logic high level, the parallelizer 360 may generate the first input data signal DED being at a logic level corresponding to the logic level of the reception data DA2. When the second reception clock signal RICKB is at a logic high level, the parallelizer 360 may generate the second input data signal DOD being at a logic level corresponding to the logic level of the reception data DA2.

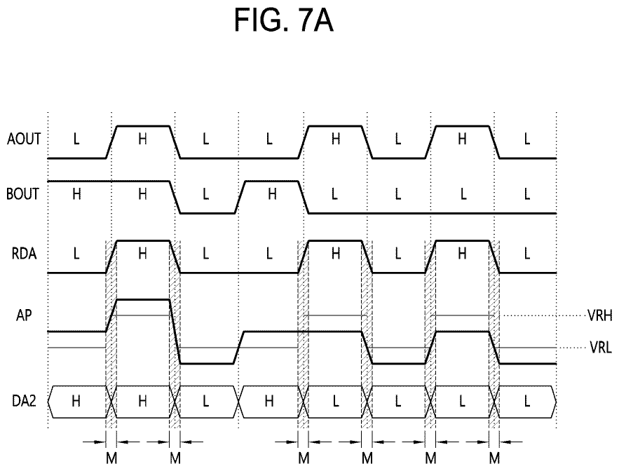

FIG. 6 is a timing diagram illustrating an overall operation of the semiconductor device 300 according to an embodiment. Referring to FIGS. 5 and 6, the shifting circuit 350 may receive the first output data signals EDA that are synchronized with the first transmission clock signal TICK, that is, 0, 2, 4, 6, 8, 10, 12, and 14, and the second output data signals ODA that are synchronized with the second transmission clock signal TICKB, that is, 1, 3, 5, 7, 9, 11, 13, and 15. The duration of each of the first and second output data signals EDA and ODA may correspond to 1 cycle of the first transmission clock signal TICK or the second transmission clock signal TICKB. The shifting circuit 350 may align the first output data signal EDA with a rising edge of the second transmission clock signal TICKB, and may align the second output data signal ODA with a rising edge of the first transmission clock signal TICK. Whenever a rising edge of the second transmission clock signal TICKB occurs, the eight first output data signals EDA that have been aligned, that is, 0, 2, 4, 6, 8, 10, 12, and 14, may be sequentially provided from the shifting circuit 350 to the serializer 310. Whenever a rising edge of the first transmission clock signal TICK occurs, the eight second output data signals ODA that have been aligned, that is, 1, 3, 5, 7, 9, 11, 13, and 15, may be sequentially provided from the shifting circuit 350 to the serializer 310. The serializer 310 may generate the transmission data DA1 from each of the first and second output data signals EDA and ODA in synchronization with each of the first and second transmission clock signals TICK and TICKB. The serializer 310 samples the aligned first output data signal EDA using the first transmission clock signal TICK, and samples the aligned second output data signal ODA using the second transmission clock signal TICKB. Accordingly, a setup margin corresponding to about a half cycle of the first transmission clock signal TICK or the second transmission clock signal TICKB can be established or secured to generate the transmission data DA1 from each of the first and second output data signals EDA and ODA. The serializer 310 may output the eight first output data signal EDA that have been aligned, that is, 0, 2, 4, 6, 8, 10, 12, and 14, as a first bit, third bit, fifth bit, seventh bit, ninth bit, eleventh bit, thirteenth bit, and fifteenth bit of the transmission data DA1, respectively, whenever a rising edge of the first transmission clock signal TICK occurs. The serializer 310 may output the eight second output data signals ODA, that is, 1, 3, 5, 7, 9, 11, 13, and 15, as a second bit, fourth bit, sixth bit, eighth bit, tenth bit, twelfth bit, fourteenth bit, and sixteenth bit of the transmission data DA1, respectively, whenever a rising edge of the second transmission clock signal TICKB occurs. The first to sixteenth bits of the transmission data DA1 may each have duration corresponding to half a cycle of the first transmission clock signal TICK or the second transmission clock signal TICKB. The transmission circuit 320 may output the output voltage AOUT to the node AP based on the transmission data DA1.

The delay circuit 340 may generate the first delay data signal RED and the second delay data signal ROD by delaying the aligned first output data signal EDA and the aligned second output data signal ODA, respectively. The delay circuit 340 may delay the aligned first data signal EDA and the aligned second data signal ODA by a time duration corresponding to the propagation delay of the serializer 310 and the transmission circuit 320. The delay circuit 340 generates the first and second delay data signals RED and ROD by delaying the aligned first and second output data signals EDA and ODA by the time duration corresponding to the propagation delay of the serializer 310 and the transmission circuit 320. In contrast, the serializer 310 samples the aligned first and second output data signals EDA and ODA as the first and second transmission clock signals TICK and TICKB that have been aligned in synchronization with the second and first transmission clock signals TICKB and TICK, respectively. Accordingly, the first and second delay data signals RED and ROD may each have a phase that is earlier than the phase of the transmission data DA1. For example, the first and second delay data signals RED and ROD may each have a phase that is earlier than the phase of the transmission data DA1 by a time that is shorter than a half cycle of each of the first and second transmission clock signals TICK and TICKB (e.g., about a quarter (¼) of a cycle of each of the first and second transmission clock signals TICK and TICKB). Accordingly, the duration of the first and second delay data signals RED and ROD may surround pieces of unit duration (0, 1, 2, 3, 4, 5, 6, 7, 8, 9, 10, 11, 12, 13, 14, and 15) of the node AP. The first delay data signals RED, that is, 0, 2, 4, 6, 8, 10, 12, and 14, may surround the pieces of first, third, fifth, seventh, ninth, eleventh, thirteenth, and fifteenth unit duration (0, 2, 4, 6, 8, 10, 12, and 14) of the node AP, respectively. The second delay data signals ROD, that is, 1, 3, 5, 7, 9, 11, 13, and 15, may surround the pieces of second, fourth, sixth, eighth, tenth, twelfth, fourteenth, and sixteenth unit duration (1, 3, 5, 7, 9, 11, 13, and 15) of the node AP, respectively. When the unit duration of the node AP is included in the duration of each of the first and second delay data RED and ROD, a margin for allowing the reception circuit 330 to sample the voltage level of the node AP might not be reduced although a mismatch occurs between the delay time duration of the delay circuit 340 and the propagation delay of the serializer 310 and the transmission circuit 320.

When the first and second reception clock signals RICK and RICKB each have the same phase as the first and second transmission clock signals TICK and TICKB, the edge of the first and second reception clock signals RICK and RICKB may be aligned with an edge of the unit duration of the node AP. Although the edge of the first and second reception clock signals RICK and RICKB is aligned with the edge of the unit duration of the node AP, the sampling margin of the reception circuit 330 can be sufficiently established or secured. However, when the first and second reception clock signals RICK and RICKB each have a phase that is later than that of each of the first and second transmission clock signals TICK and TICKB by a quarter (¼) of a cycle, the edge of each of the first and second reception clock signals RICK and RICKB may be aligned with the center of the unit duration of the node AP. When the edges of the first and second reception clock signals RICK and RICKB are aligned with the center of the unit duration of the node AP, the sampling margin of the reception circuit 330 may become a maximum.

Whenever the first reception clock signal RICK is at a logic high level, the sampling circuit 331 may generate the first and second detection signals DS1 and DS2 by comparing the voltage level of the node AP with the first and second reference voltages VRH and VRL. The selection circuit 332 may output one of the first and second detection signals DS1 and DS2 as each of the first bit, third bit, fifth bit, seventh bit, ninth bit, eleventh bit, thirteenth bit and fifteenth bit of the reception data DA2 based on the logic level of the first delay data RED. Whenever the second reception clock signal RICKB is at a logic high level, the sampling circuit 331 may generate the third and fourth detection signals DS3 and DS4 by comparing the voltage level of the node AP with the first and second reference voltages VRH and VRL. The selection circuit 332 may output one of the third and fourth detection signals DS3 and DS4 as each of the second bit, fourth bit, sixth bit, eighth bit, tenth bit, twelfth bit, fourteenth bit, and sixteenth bit of the reception data DA2 based on the logic level of the second delay data ROD.

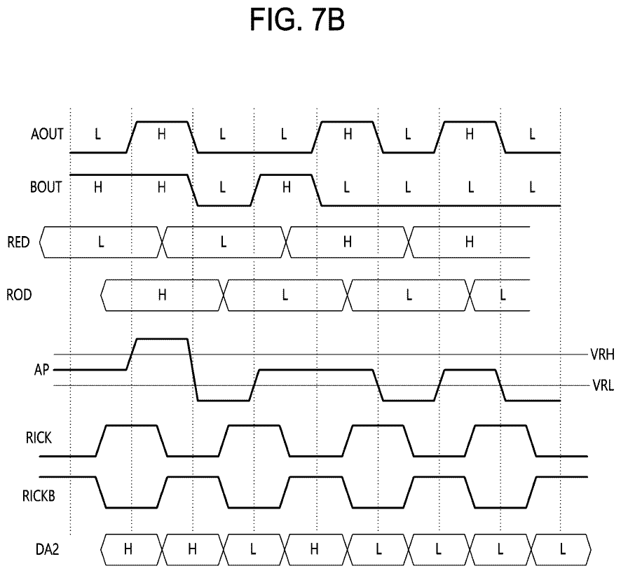

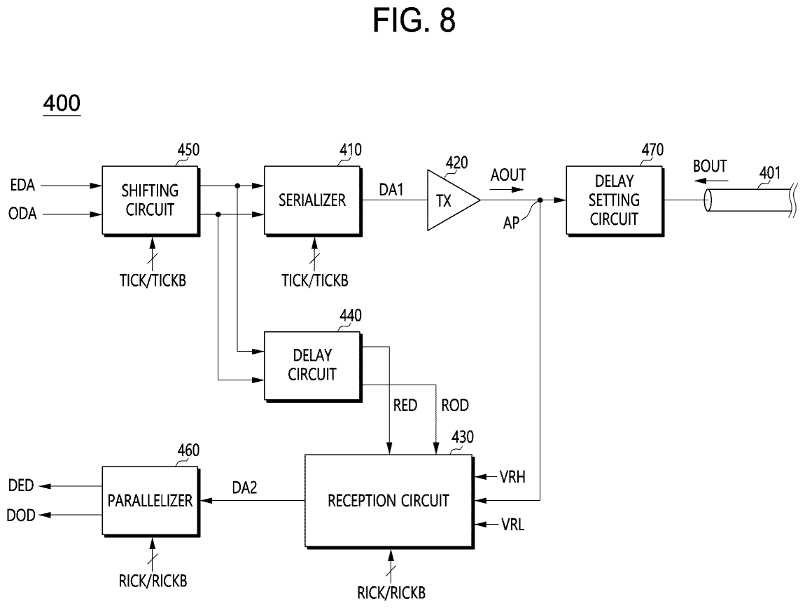

FIG. 7A is a timing diagram illustrating an operation of the first semiconductor device 210 illustrated in FIG. 3. Referring to FIGS. 3 and 7A, the first output voltage AOUT that is generated by the transmission circuit 211 and the second output voltage BOUT that is transmitted by the second semiconductor device 220 through the signal transmission line 201 may be superposed at the first node AP of the first semiconductor device 210. When the delay circuit 212 accurately replicates the propagation delay of the transmission circuit 211, the delay data RDA may have substantially the same phase as the first output voltage AOUT. However, when a mismatch occurs between the delay time duration of the delay circuit 212 and the propagation delay of the transmission circuit 211, the delay data RDA may be out of phase with the first output voltage AOUT. For example, the delay data RDA may have a phase that is changed within a mismatch time range M that is shaded. The reception circuit 213 may select one of the first and second reference voltages VRH and VRL based on the delay data RDA, and may generate the reception data DA2 by comparing the voltage level of the first node AP with the voltage level of the selected one reference voltage. When the phase of the delay data RDA is earlier than the phase of the first output voltage AOUT, the valid window of previous data may be reduced because the voltage level of the reference voltage is changed before the sampling of the previous data is completed. On the contrary, when the phase of the delay data RDA is later than the phase of the first output voltage AOUT, the valid window of current data may be reduced because timing at which the reference voltage for the sampling of the current data is selected is delayed. Accordingly, the valid window of the reception data DA2 may be reduced by a time corresponding to the mismatch time range M. A reduction in the valid window of the reception data DA2 may reduce operation reliability of the first semiconductor device 210. As the semiconductor system 200 operates at a high speed, a reduction in the valid window may result in greater loss. Furthermore, a settling time that is taken for the voltage level of one reference voltage to be changed into the voltage level of another reference voltage may occur because the reception circuit 213 selects the first and second reference voltages VRH and VRL based on the logic level of the delay data RDA. The settling time may further reduce the valid window of the reception data DA2.

FIG. 7B is a timing diagram illustrating an operation of the semiconductor device 300 illustrated in FIG. 5. Referring to FIGS. 5 and 7B, the output voltage AOUT that is generated by the transmission circuit 320 and the output voltage BOUT that is transmitted by another semiconductor device through the signal transmission line 301 may be superposed at the node AP. The reception circuit 330 may detect the voltage level of the node AP based on the first and second data signals EDA and ODA and not the transmission data DA1. When the first reception clock signal RICK is at a logic high level, the reception circuit 330 may generate each of the first and second detection signals DS1 and DS2 by comparing the voltage level of the node AP with each of the first and second reference voltages VRH and VRL. The reception circuit 330 may output one of the first and second detection signals DS1 and DS2 as the reception data DA2 based on the logic level of the first delay data signal RED. When the second reception clock signal RICKB is at a logic high level, the reception circuit 330 may generate each of the third and fourth detection signals DS3 and DS4 by comparing the voltage level of the node AP with each of the first and second reference voltages VRH and VRL. The reception circuit 330 may output one of the third and fourth detection signals DS3 and DS4 as the reception data DA2 based on the logic level of the second delay data signal ROD. Accordingly, a margin in which the reception data DA2 may be sampled based on the voltage level of the node AP can be increased to one cycle of the first reception clock signal RICK or the second reception clock signal RICKB. The reception circuit 330 does not need to consider the settling time of the reference voltage because the reception circuit 330 does not select the first and second reference voltages VRH and VRL, the voltage level of each of which is compared with the voltage level of the node AP. Furthermore, an operation margin of the reception circuit 330 may be sufficient although a mismatch occurs between the voltage level of the node AP and each of the first and second delay data signals RED and ROD because the edge of each of the first and second reception clock signals RICK and RCIKB can be aligned with the center of each of the first and second delay data signals RED and ROD. Accordingly, the valid window of the reception data DA2 might not be reduced. The mismatch that occurs between the output voltage AOUT and the first delay data signal RED might not have any influence on an operation of the reception circuit 330 generating the reception data DA2 based on the voltage level of the node AP in synchronization with the first reception clock signal RICK. Furthermore, any mismatch that occurs between the output voltage AOUT and the second delay data signal ROD might not have any influence on an operation of the reception circuit 330 generating the reception data DA2 based on the voltage level of the node AP in synchronization with the second reception clock signal RICKB.

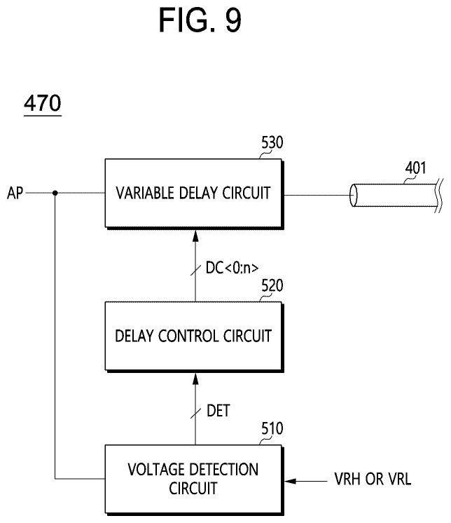

FIG. 8 is a diagram illustrating a configuration of a semiconductor device 400 according to an embodiment. Referring to FIG. 8, the semiconductor device 400 may be electrically coupled to another semiconductor device through a signal transmission line 401. The semiconductor device 400 may include a serializer 410, a transmission circuit (TX) 420, a reception circuit 430, a delay circuit 440, a shifting circuit 450, a parallelizer 460, and a delay setting circuit 470. The semiconductor device 400 may include substantially the same components as the semiconductor device 300 illustrated in FIG. 5 in addition to the delay setting circuit 470. The serializer 410, the transmission circuit 420, the reception circuit 430, the delay circuit 440, the shifting circuit 450, and the parallelizer 460 may be substantially the same components as and may perform substantially the same functions as the serializer 310, the transmission circuit 320, the reception circuit 330, the delay circuit 340, the shifting circuit 350, and the parallelizer 360 illustrated in FIG. 5, respectively, and thus, redundant descriptions of the same components are omitted. The delay setting circuit 470 may be electrically coupled between the node AP and the signal transmission line 401. The delay setting circuit 470 may be electrically coupled to the transmission circuit 420 and the reception circuit 430 through the node AP. The delay setting circuit 470 may change a propagation delay time duration between the node AP and the signal transmission line 401. The delay setting circuit 470 may set the sum of the delay time duration of the delay setting circuit 470 and the propagation delay time duration of the signal transmission line 401 so that the sum corresponds to a multiple of a unit time. The unit time may correspond to the duration of transmission data DA1, and may correspond to a half cycle of a first transmission clock signal TICK or a second transmission clock signal TICKB. The delay setting circuit 470 can improve the accuracy of SBD communication of the semiconductor device 400 and a semiconductor system including the semiconductor device 400 by minimizing an interval in which the voltage level of the node AP transitions. The delay setting circuit 470 may change the delay time duration of the delay setting circuit 470 by detecting the voltage level of the node AP. The delay setting circuit 470 may receive at least one of a first reference voltage VRH and a second reference voltage VRL, and may use the at least one reference voltage to detect the voltage level of the node AP.

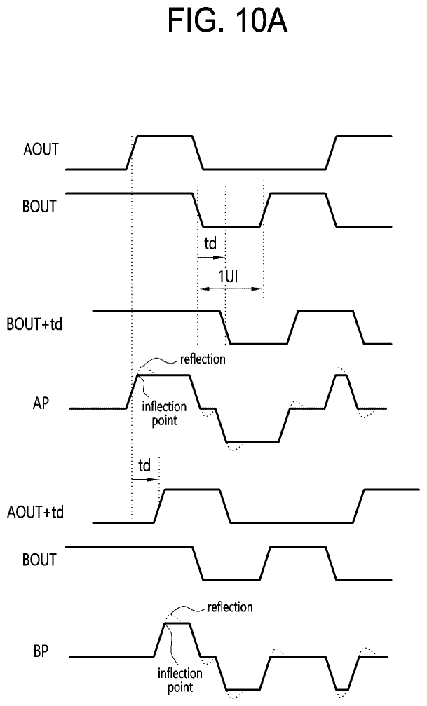

FIG. 9 is a diagram illustrating a configuration of the delay setting circuit 470 illustrated in FIG. 8. Referring to FIG. 9, the delay setting circuit 470 may include a voltage detection circuit 510, a delay control circuit 520, and a variable delay circuit 530. The voltage detection circuit 510 may be electrically coupled to the node AP, and may receive at least one of the first reference voltage VRH and the second reference voltage VRL. The voltage detection circuit 510 may generate a voltage detection signal DET by comparing the voltage level of the node AP with one of the first and second reference voltages VRH and VRL. For example, when an interval in which the voltage level of the node AP is higher than the first reference voltage VRH or an interval in which the voltage level of the node AP is lower than the second reference voltage VRL is present in the voltage level of the node AP, the voltage detection circuit 510 may enable the voltage detection signal DET. When the voltage level of the node AP is changed to be between the first reference voltage VRH and the second reference voltage VRL, the voltage detection circuit 510 may maintain the voltage detection signal DET in a disabled state. The delay control circuit 520 may receive the voltage detection signal DET, and may generate a delay control signal DC<0:n> based on the voltage detection signal DET. The delay control signal DC<0:n> may be a digital code signal including a plurality of bits. In this case, “n” may be an arbitrary natural number. The delay control circuit 520 may increase the value of the delay control signal DC<0:n> based on the voltage detection signal DET. For example, the delay control circuit 520 may increase the value of the delay control signal DC<0:n> from a default value in stages whenever the voltage detection signal DET is enabled. The delay control circuit 520 may increase the delay time duration of the variable delay circuit 530 by increasing the value of the delay control signal DC<0:n>. The variable delay circuit 530 may receive the delay control signal DC<0:n> from the delay control circuit 520. The delay time duration of the variable delay circuit 530 may be changed based on the delay control signal DC<0:n>. As the value of the delay control signal DC<0:n> is increased, the delay time duration of the variable delay circuit 530 may be increased. As the value of the delay control signal DC<0:n> is decreased, the delay time duration of the variable delay circuit 530 may be decreased.

To set the delay time duration of the delay setting circuit 470, an output voltage AOUT of the semiconductor device 400 may be set to have a pattern of 0101. An output voltage BOUT that is transmitted by another semiconductor device through the signal transmission line 401 may also be set to have a pattern of 0101. When the sum of the delay time duration of the signal transmission line 410 and the delay time duration of the variable delay circuit 530 does not correspond to a unit time, an interval in which the voltage level of the node AP is higher than the first reference voltage VRH or an interval in which the voltage level of the node AP is lower than the second reference voltage VRL may be present because the output voltages AOUT and BOUT are superposed and misaligned. The voltage detection circuit 510 may enable the voltage detection signal DET. The delay control circuit 520 may increase the delay time duration of the variable delay circuit 530 by increasing the value of the delay control signal DC<0:n>. When the delay time duration of the variable delay circuit 530 is increased and the sum of the delay time duration of the variable delay circuit 530 and the delay time duration of the signal transmission line 401 corresponds to a multiple of a unit time, an interval in which the voltage level of the node AP is higher than the first reference voltage VRH or an interval in which the voltage level of the node AP is lower than the second reference voltage VRL might not be present as the output voltages AOUT and BOUT are brought into better alignment. When the voltage detection circuit 510 does not enable the voltage detection signal DET, the delay control circuit 520 may maintain the delay time duration of the variable delay circuit 530 by maintaining the value of the delay control signal DC<0:n>.

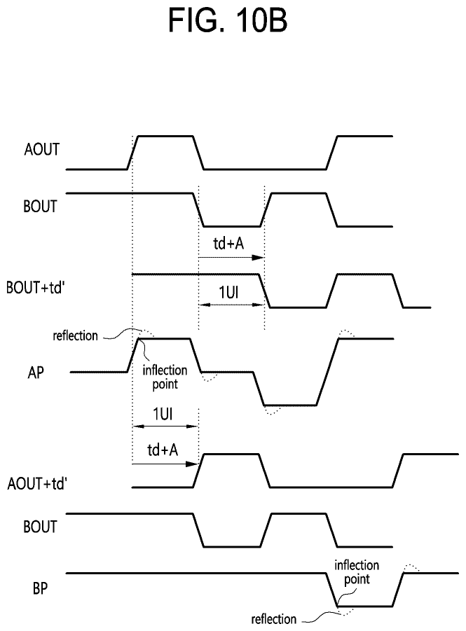

FIG. 10A is a timing diagram illustrating an operation of a semiconductor device that does not include the delay setting circuit 470 illustrated in FIG. 8. FIG. 10B is a timing diagram illustrating an operation of the semiconductor device 400 illustrated in FIG. 8. Referring to FIG. 10A, if the delay setting circuit 470 is not included, the voltage level of the node AP may correspond to the sum of output voltages “BOUT+td”, that is, the output voltage AOUT that is output by the transmission circuit 420 and the output voltage BOUT that is output by the other semiconductor device, which have been delayed by the delay time duration of the signal transmission line 401. When the delay time duration “td” of the signal transmission line 401 is shorter than a unit time UI as illustrated in FIG. 10A, many inflection points, for example, six inflection points may occur in the voltage level of the node AP, and the number of times that the voltage level of the node AP transitions may be increased. When the number of times that the voltage level of the node AP transitions is increased, it may be difficult for the reception circuit 430 to accurately sample the reception data DA2 based on the voltage level of the node AP because a lot of reflection occurs in the voltage level of the node AP as indicated by dotted lines. Although not illustrated in FIG. 8, the sum of an output voltage “AOUT+td”, that is, the output voltage AOUT that has been delayed by the delay time duration “td” of the signal transmission line 401, and the output voltage BOUT may correspond to the voltage level of the node BP of the other semiconductor device. When the delay time duration “td” of the signal transmission line 401 is shorter than the unit time UI, the voltage level of the node BP may include many inflection points, for example, six inflection points like the voltage level of the node AP. And reflection occurs in the voltage level of the node BP as indicated by dotted line at every inflection points.

Referring to FIG. 10B, if the delay setting circuit 470 is included and the sum “td+A” of the delay time duration A of the delay setting circuit 470 and the delay time duration “td” of the signal transmission line 401 is set as the unit time UI, the time when the voltage level of the output voltage AOUT that is output by the transmission circuit 420 transitions and the time when the voltage level of an output voltage “BOUT+td′” that is transmitted by the other semiconductor device transitions may become substantially the same. Accordingly, the least inflection point, for example, four inflection points may occur in the voltage level of the node AP, and the number of times that the voltage level of the node AP transitions can be reduced. As the number of times that the voltage level of the node AP transitions is reduced, reflection in the voltage level of the node AP is also reduced and the reception circuit 430 can generate the reception data DA2 that are more accurate based on the voltage level of the node AP because reflection that occurs in the voltage level of the node AP is reduced. Likewise, the time when the voltage level of an output voltage “AOUT+td′” that is transmitted through the delay setting circuit and the signal transmission line transitions and the time when the output voltage BOUT transitions may become substantially the same at the node BP of the other semiconductor device. Accordingly, the voltage level of the node BP of the other semiconductor device may also have the least inflection point, for example two inflection points, and the number of times that the voltage level of the node BP transitions can be reduced.

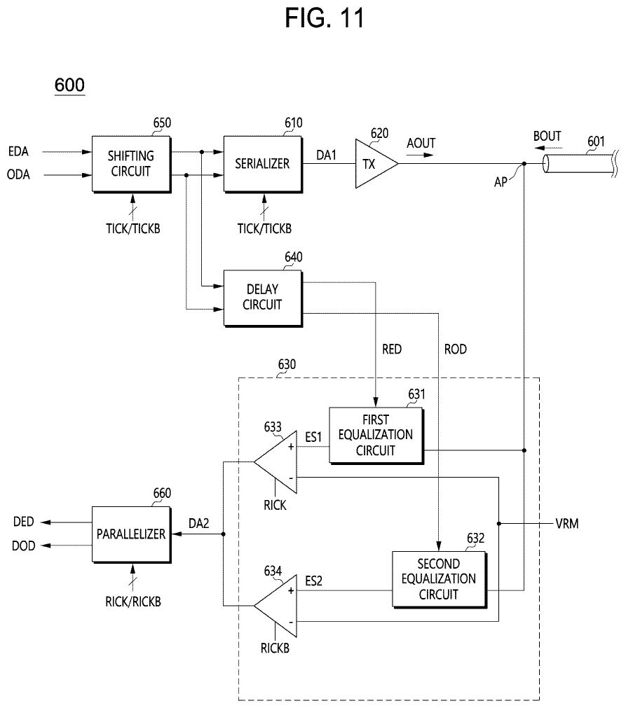

FIG. 11 is a diagram illustrating a configuration of a semiconductor device 600 according to an embodiment. The semiconductor device 600 may be electrically coupled to another semiconductor device through a signal transmission line 601. The semiconductor device 600 may be electrically coupled to the signal transmission line 601 through a node AP. The semiconductor device 600 may include a serializer 610, a transmission circuit (TX) 620, a reception circuit 630, a delay circuit 640, a shifting circuit 650, and a parallelizer 660. The semiconductor device 600 may have substantially the same components as the semiconductor device 300 illustrated in FIG. 5 in addition to the reception circuit 630, and thus redundant descriptions of the same components are omitted. The reception circuit 630 may be electrically coupled to the node AP, and may receive a first reception clock signal RICK, a second reception clock signal RICKB, a first delay data signal RED, and a second delay data signal ROD. The reception circuit 630 may generate reception data DA2 by detecting the voltage level of the node AP, based on the first reception clock signal RICK, the second reception clock signal RICKB, the first delay data signal RED, and the second delay data signal ROD. The reception circuit 630 may receive a third reference voltage VRM to detect the voltage level of the node AP. The third reference voltage VRM may have a middle voltage level between the first and second reference voltages VRH and VRL illustrated in FIG. 5, and may have a voltage level corresponding to a middle voltage level of the node AP. The reception circuit 630 may change the voltage level of the node AP based on the first and second delay data signals RED and ROD, and may generate the reception data DA2 by comparing the changed voltage level and the third reference voltage VRM.

The reception circuit 630 may include a first equalization circuit 631, a second equalization circuit 632, a first comparator 633, and a second comparator 634. The first equalization circuit 631 may be electrically coupled to the node AP, and may receive the first delay data signal RED. The first equalization circuit 631 may generate a first equalization signal ES1 by equalizing the voltage level of the node AP based on the voltage level of the first delay data signal RED. The first equalization circuit 631 may generate the first equalization signal ES1 by changing the voltage level of the node AP by using the first delay data signal RED as a coefficient. When the logic level of the first delay data signal RED is a logic low level, the first equalization circuit 631 may generate the first equalization signal ES1 having a voltage level higher than the voltage level of the node AP by raising the voltage level of the node AP. When the logic level of the first delay data signal RED is a logic high level, the first equalization circuit 631 may generate the first equalization signal ES1 having a voltage level lower than the voltage level of the node AP by decreasing the voltage level of the node AP. The second equalization circuit 632 may be electrically coupled to the node AP, and may receive the second delay data signal ROD. The second equalization circuit 632 may generate a second equalization signal ES2 by equalizing the voltage level of the node AP based on the second delay data signal ROD. The second equalization circuit 632 may generate the second equalization signal ES2 by changing the voltage level of the node AP by using the second delay data signal ROD as a coefficient. When the logic level of the second delay data signal ROD is a logic low level, the second equalization circuit 632 may generate the second equalization signal ES2 having a voltage level higher than the voltage level of the node AP by raising the voltage level of the node AP. When the logic level of the second delay data signal ROD is a logic high level, the second equalization circuit 632 may generate the second equalization signal ES2 having a voltage level lower than the voltage level of the node AP by decreasing the voltage level of the node AP.

The first comparator 633 may receive the first reception clock signal RICK, the first equalization signal ES1, and the third reference voltage VRM. The first comparator 633 may be activated based on the first reception clock signal RICK. The first comparator 633 may generate the reception data DA2 by comparing the first equalization signal ES1 with the third reference voltage VRM in synchronization with the first reception clock signal RICK. For example, when the first reception clock signal RICK is at a logic high level, the first comparator 633 may generate the reception data DA2 by comparing the first equalization signal ES1 and the third reference voltage VRM. The second comparator 634 may receive the second reception clock signal RICKB, the second equalization signal ES2, and the third reference voltage VRM. The second comparator 634 may be activated based on the second reception clock signal RICKB. The second comparator 634 may generate the reception data DA2 by comparing the second equalization signal ES2 with the third reference voltage VRM in synchronization with the second reception clock signal RICKB. For example, when the second reception clock signal RICKB is at a logic high level, the second comparator 634 may generate the reception data DA2 by comparing the second equalization signal ES2 and the third reference voltage VRM.

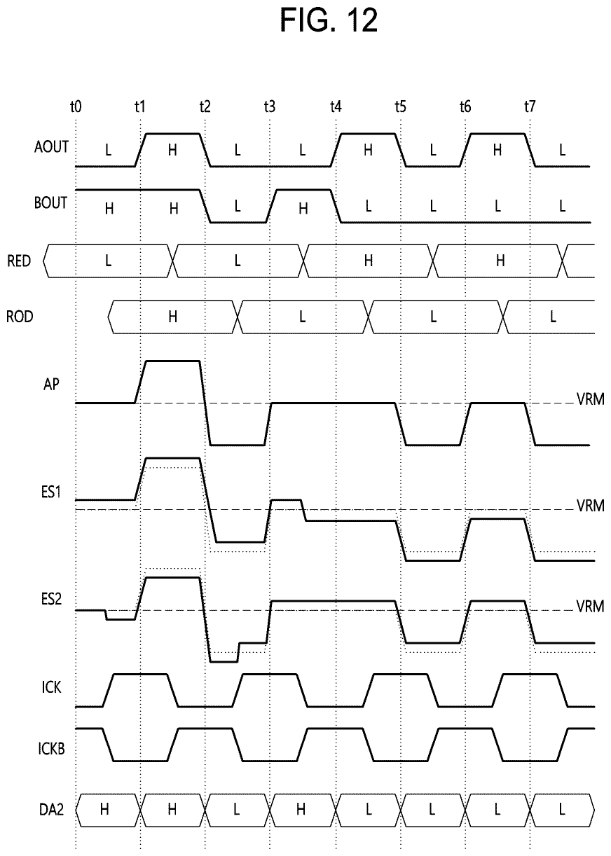

FIG. 12 is a timing diagram illustrating an operation of the semiconductor device 600 illustrated in FIG. 11. Referring to FIGS. 11 and 12, an output voltage AOUT that is generated by the transmission circuit 620 and an output voltage BOUT that is transmitted by the other semiconductor device through the signal transmission line 601 may be superposed at the node AP. The reception circuit 630 may detect the voltage level of the node AP based on first and second data signals EDA and ODA and not the transmission data DA1. The first equalization circuit 631 may generate the first equalization signal ES1 by equalizing the first delay data signal RED and the voltage level of the node AP. The second equalization circuit 632 may generate the second equalization signal ES2 by equalizing the second delay data signal ROD and the voltage level of the node AP. In an interval in which the first delay data signal RED is at a logic low level, the first equalization signal ES1 may have a voltage level higher than the voltage level of the node AP. In an interval in which the first delay data signal RED is at a logic high level, the first equalization signal ES1 may have a voltage level lower than the voltage level of the node AP. In an interval in which the second delay data signal ROD is at a logic high level, the second equalization signal ES2 may have a voltage level lower than the voltage level of the node AP. In an interval in which the second delay data signal ROD is at a logic low level, the second equalization signal ES2 may be at a voltage level higher than the voltage level of the node AP.

In an interval between times to and t1, in synchronization with the first rising edge of the first reception clock signal RICK, the first comparator 633 may generate a first bit of the reception data DA2, which is at a logic high level, by comparing the first equalization signal ES1 and the third reference voltage VRM. In an interval between times t1 and t2, in synchronization with the first rising edge of the second reception clock signal RICKB, the second comparator 634 may generate a second bit of the reception data DA2, which is at a logic high level, by comparing the second equalization signal ES2 and the third reference voltage VRM. In an interval between times t2 and t3, in synchronization with the second rising edge of the first reception clock signal RICK, the first comparator 633 may generate a third bit of the reception data DA2, which is at a logic low level, by comparing the first equalization signal ES1 and the third reference voltage VRM. In an interval between times t3 and t4, in synchronization with the second rising edge of the second reception clock signal RICKB, the second comparator 634 may generate a fourth bit of the reception data DA2, which is at a logic high level, by comparing the second equalization signal ES2 and the third reference voltage VRM. In an interval between times t4 and t5, in synchronization with the third rising edge of the first reception clock signal RICK, the first comparator 633 may generate a fifth bit of the reception data DA2, which is at a logic low level, by comparing the first equalization signal ES1 and the third reference voltage VRM. In an interval between times t5 and t6, in synchronization with the third rising edge of the second reception clock signal RICKB, the second comparator 634 may generate a sixth bit of the reception data DA2, which is at a logic low level, by comparing the second equalization signal ES2 and the third reference voltage VRM. In an interval between times t6 and t7, in synchronization with the fourth rising edge of the first reception clock signal RICK, the first comparator 633 may generate a seventh bit of the reception data DA2, which is at a logic low level, by comparing the first equalization signal ES1 and the reference voltage VRM. After time t7, in synchronization with the fourth rising edge of the second reception clock signal RICKB, the second comparator 634 may generate an eighth bit of the reception data DA2, which is at a logic low level, by comparing the second equalization signal ES2 and the reference voltage VRM.

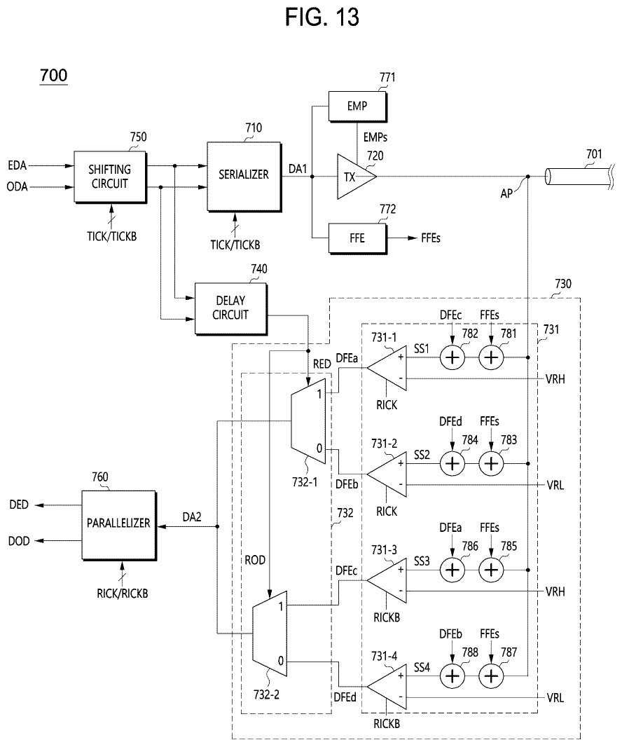

FIG. 13 is a diagram illustrating a configuration of a semiconductor device 700 according to an embodiment. Referring to FIG. 13, the semiconductor device 700 may include a serializer 710, a transmission circuit (TX) 720, a reception circuit 730, a delay circuit 740, a shifting circuit 750, and a parallelizer 760. The serializer 710, the transmission circuit 720, the delay circuit 740, the shifting circuit 750, and the parallelizer 760 may be substantially the same components as the serializer 310, the transmission circuit 320, the delay circuit 340, the shifting circuit 350, and the parallelizer 360 illustrated in FIG. 5, respectively, and thus redundant descriptions of the same components are omitted. The semiconductor device 700 may additionally employ methods, such as transmission equalization, reception equalization, and noise compensation, to improve signal integrity in a node AP and to reduce a signal loss in a channel.

The semiconductor device 700 may further include a pre-emphasis circuit (EMP) 771 and a feed forward equalization circuit (FFE) 772. The pre-emphasis circuit 771 may implement the transmission equalization. The feed forward equalization circuit 772 may implement the noise compensation. The pre-emphasis circuit 771 may receive transmission data DA1 that are output by the serializer 710, and may generate emphasis control signal EMPs based on the transmission data DA1. The pre-emphasis circuit 771 may provide the emphasis control signal EMPs to the transmission circuit 720. When driving a node AP based on transmission data DA2, the transmission circuit 720 may increase the transition slope of the voltage level of the node AP based on the emphasis control signal EMPs.

The feed forward equalization circuit 772 may receive the transmission data DA1, and may generate a feed forward control signal FFEs based on the transmission data DA1. The feed forward equalization circuit 772 may generate the feed forward control signal FFEs that has a voltage level complementary to the voltage level of the transmission data DA1 and that has a swing range smaller than the swing range of the transmission data DA1. The feed forward equalization circuit 772 may provide the feed forward control signal FFEs to the reception circuit 730.

Like the reception circuit 330 illustrated in FIG. 5, the reception circuit 730 may include a sampling circuit 731 and a selection circuit 732. The sampling circuit 731 includes a first comparator 731-1, a second comparator 731-2, a third comparator 732-3, and a fourth comparator 731-4, and may further include first to eighth summation circuits 781, 782, 783, 784, 785, 786, 787, and 788. The first comparator 731-1 may generate a first detection signal DFEa by comparing a first summation signal SS1 and a first reference voltage VRH in synchronization with a first reception clock signal RICK. The second comparator 731-2 may generate a second detection signal DFEb by comparing a second summation signal SS2 and a second reference voltage VRL in synchronization with the first reception clock signal RICK. The third comparator 731-3 may generate a third detection signal DFEc by comparing a third summation signal SS3 and the first reference voltage VRH in synchronization with a second reception clock signal RICKB. The fourth comparator 731-4 may generate a fourth detection signal DFEd by comparing a fourth summation signal SS4 and the second reference voltage VRL in synchronization with the second reception clock signal RICKB.

The first summation circuit 781 may receive the feed forward control signal FFEs and sum up the feed forward control signal FFEs and the voltage level of the node AP. The second summation circuit 782 may receive the output signal of the first summation circuit 781 and the third detection signal DFEc. The second summation circuit 782 may generate the first summation signal SS1 by summing up the output signal of the first summation circuit 781 and the third detection signal DFEc. The third summation circuit 783 may receive the feed forward control signal FFEs and sum up the feed forward control signal FFEs and the voltage level of the node AP. The fourth summation circuit 784 may receive the output signal of the third summation circuit 783 and the fourth detection signal DFEd. The fourth summation circuit 784 may generate the second summation signal SS2 by summing up the output signal of the third summation circuit 783 and the fourth detection signal DFEd. The fifth summation circuit 785 may receive the feed forward control signal FFEs and sum up the feed forward control signal FFEs and the voltage level of the node AP. The sixth summation circuit 786 may receive the output signal of the fifth summation circuit 785 and the first detection signal DFEa. The sixth summation circuit 786 may generate the third summation signal SS3 by summing up the output signal of the fifth summation circuit 785 and the first detection signal DFEa. The seventh summation circuit 787 may receive the feed forward control signal FFEs and sum up the feed forward control signal FFEs and the voltage level of the node AP. The eighth summation circuit 788 may receive the output signal of the seventh summation circuit 787 and the second detection signal DFEb. The eighth summation circuit 788 may generate the fourth summation signal SS4 by summing up the output signal of the seventh summation circuit 787 and the second detection signal DFEb. The second summation circuit 782, the fourth summation circuit 784, the sixth summation circuit 786, and the eighth summation circuit 788 may each implement the reception equalization by operating as a decision feedback equalization circuit.

The selection circuit 732 may include a first multiplexer 732-1 and a second multiplexer 732-2. The first multiplexer 732-1 may receive a first delay data signal RED, the first detection signal DFEa, and the second detection signal DFEb. When the first delay data signal RED is at a first logic level, the first multiplexer 732-1 may output the first detection signal DFEa as the reception data DA2. When the first delay data signal RED is at a second logic level, the first multiplexer 732-1 may output the second detection signal DFEb as the reception data DA2. The second multiplexer 732-2 may receive a second delay data signal ROD, the third detection signal DFEc, and the fourth detection signal DFEd. When the second delay data signal ROD is at the first logic level, the second multiplexer 732-2 may output the third detection signal DFEc as the reception data DA2. When the second delay data signal ROD is at the second logic level, the second multiplexer 732-2 may output the fourth detection signal DFEd as the reception data DA2.

In an embodiment, at least one of the transmission equalization, the reception equalization, and the noise compensation may be applied to the semiconductor device 700. For example, the semiconductor device 700 may employ only the noise compensation without the reception equalization, or may employ only the reception equalization without the noise compensation. If the semiconductor device 700 employs the noise compensation, the semiconductor device might include the feed forward equalization circuit 772 and the first, third, fifth, and seventh summation circuits 781, 783, 785, and 787, and might not include the second, fourth, sixth, and eighth summation circuits 782, 784, 786, and 788. In this case, the first comparator 731-1 may be modified to receive the output signal of the first summation circuit 781, the second comparator 731-2 may be modified to receive the output signal of the third summation circuit 783, the third comparator 731-3 may be modified to receive the output signal of the fifth summation circuit 785, and the fourth comparator 731-4 may be modified to receive the output of the seventh summation circuit 787. If the semiconductor device 700 employs the reception equalization, the semiconductor device 700 might include the second, fourth, sixth, and eighth summation circuits 782, 784, 786, and 788 and might not include the feed forward equalization circuit 772 and the first, third, fifth, and seventh summation circuits 781, 783, 785, and 787. In this case, the second summation circuit 782 may be modified to sum up the voltage level of the node AP and the third detection signal DFEc, the fourth summation circuit 784 may be modified to sum up the voltage level of the node AP and the fourth detection signal DFEd, the sixth summation circuit 786 may be modified to sum up the voltage level of the node AP and the first detection signal DFEa, and the eighth summation circuit 788 may be modified to sum up the voltage level of the node AP and the second detection signal DFEb.

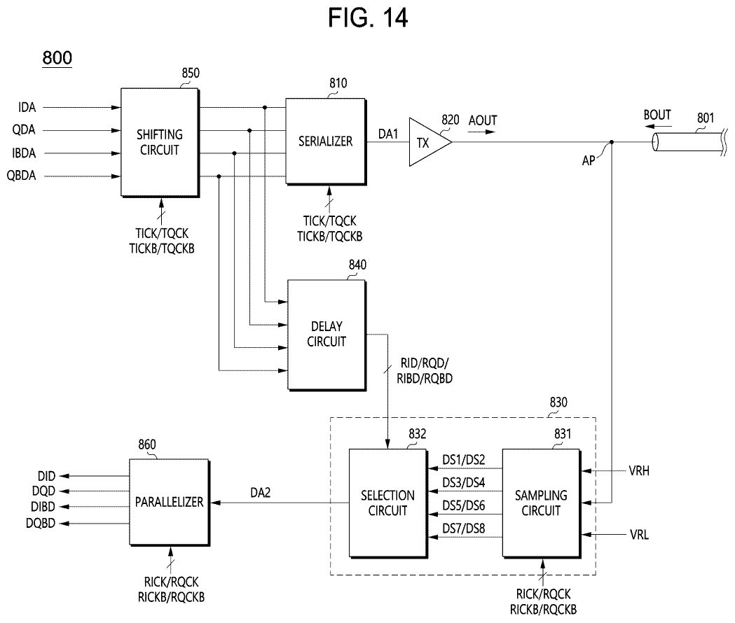

FIG. 14 is a diagram illustrating a configuration of a semiconductor device 800 according to an embodiment. Referring to FIG. 14, the semiconductor device 800 may be electrically coupled to a signal transmission line 801, and may be electrically coupled to another semiconductor device through a signal transmission line 801. The semiconductor device 800 may include a serializer 810, a transmission circuit (TX) 820, and a reception circuit 830. The serializer 810 may generate transmission data DA1 by receiving a first output data signal IDA, a second output data signal QDA, a third output data signal IBDA, a fourth output data signal QBDA, a first transmission clock signal TICK, a second transmission clock signal TQCK, a third transmission clock signal TICKB, and a fourth transmission clock signal TQCKB. The serializer 810 may generate the transmission data DA1 by serializing the first to fourth output data signals IDA, QDA, IBDA, and QBDA based on the first to fourth transmission clock signals TICK, TQCK, TICKB, and TQCKB. The first to fourth output data signals IDA, QDA, IBDA, and QBDA may each be parallel data. The transmission data DA1 may be serial data. The duration of each of the first to fourth output data signals IDA, QDA, IBDA, and QBDA may be longer than the duration of the transmission data DA1. The first to fourth transmission clock signals TICK, TOCK, TICKB, and TQCKB may each be a quarter-rate clock signal, and may have different phases. For example, the first transmission clock signal TICK may have a phase that is earlier than the phase of the second transmission clock signal TQCK by 90 degrees. The second transmission clock signal TQCK may have a phase that is earlier than the phase of the third transmission clock signal TICKB by 90 degrees. The third transmission clock signal TICKB may have a phase that is earlier than the phase of the fourth transmission clock signal TQCKB by 90 degrees. The fourth transmission clock signal TQCKB may have a phase that is earlier than the phase of the first transmission clock signal TICK by 90 degrees. The serializer 810 may output the first output data signal IDA as the transmission data DA1 in synchronization with the first transmission clock signal TICK, and may output the second output data signal QDA as the transmission data DA1 in synchronization with the second transmission clock signal TQCK. The serializer 810 may output the third output data signal IBDA as the transmission data DA1 in synchronization with the third transmission clock signal TICKB, and may output the fourth output data signal QBDA as the transmission data DA1 in synchronization with the fourth transmission clock signal TQCKB. For example, the serializer 810 may change the logic level of the transmission data DA1 based on the logic level of the first output data signal IDA at a rising edge of the first transmission clock signal TICK. The serializer 810 may change the logic level of the transmission data DA1 based on the logic level of the second output data signal QDA at a rising edge of the second transmission clock signal TQCK. The serializer 810 may change the logic level of the transmission data DA1 based on the logic level of the third output data signal IBDA at a rising edge of the third transmission clock signal TICKB. The serializer 810 may change the logic level of the transmission data DA1 based on the logic level of the fourth output data signal QBDA at a rising edge of the fourth transmission clock signal TQCKB.

The transmission circuit 820 may receive the transmission data DA1, and may drive a node AP based on the transmission data DA1. The node AP may be electrically coupled to the signal transmission line 801. The transmission circuit 820 may output, to the node AP, an output voltage AOUT corresponding to the transmission data DA1. An output voltage BOUT may be transmitted by the other semiconductor device through the signal transmission line 801. The output voltage AOUT and the output voltage BOUT that is transmitted by the other semiconductor device may be superposed at the node AP. The node AP may be at the superposed voltage level.

The reception circuit 830 may generate reception data DA2 by detecting the voltage level of the node AP, based on the first to fourth output data signals IDA, QDA, IBDA, and QBDA and first to fourth reception clock signals RICK, ROCK, RICKB, and ROCKB. The first to fourth reception clock signals RICK, ROCK, RICKB, and RQCKB may have substantially the same cycles as the first to fourth transmission clock signals TICK, TOCK, TICKB, and TQCKB, respectively. In an embodiment, the first to fourth reception clock signals RICK, ROCK, RICKB, and ROCKB and the first to fourth transmission clock signals TICK, TQCK, TICKB, and TQCKB may be generated from the same clock source. In an embodiment, the first to fourth reception clock signals RICK, ROCK, RICKB, and ROCKB may have the same phases as the first to fourth transmission clock signals TICK, TQCK, TICKB, and TQCKB, respectively. In an embodiment, the first to fourth reception clock signals RICK, ROCK, RICKB, and ROCKB may each have a phase that is later than the phase of each of the first to fourth transmission clock signals TICK, TQCK, TICKB, and TQCKB by an eighth (⅛) of a cycle. For example, the first reception clock signal RICK may have a phase that is later than the phase of the first transmission clock signal TICK by 45 degrees. The second reception clock signal RQCK may have a phase that is later than the phase of the second transmission clock signal TQCK by 45 degrees. The third reception clock signal RICKB may have a phase that is later than the phase of the third transmission clock signal TICKB by 45 degrees. The fourth reception clock signal RQCKB may have a phase that is later than the phase of the fourth transmission clock signal TQCKB by 45 degrees.

The reception circuit 830 may receive a first delay data signal RID, a second delay data signal RQD, a third delay data signal RIBD, and a fourth delay data signal RQBD. The first delay data signal RID may be generated from the first output data signal IDA, and may be generated by delaying the first output data signal IDA. The second delay data signal RQD may be generated from the second output data signal QDA, and may be generated by delaying the second output data signal QDA. The third delay data signal RIBD may be generated from the third output data signal IBDA, and may be generated by delaying the third output data signal IBDA. The fourth delay data signal RQBD may be generated from the fourth output data signal QBDA, and may be generated by delaying the fourth output data signal QBDA. The semiconductor device 800 may further include a delay circuit 840. The delay circuit 840 may receive the first to fourth output data signals IDA, QDA, IBDA, and QBDA, and may generate the first to fourth delay data signals RID, ROD, RIBD, and RQBD by delaying the first to fourth output data signals IDA, QDA, IBDA, and QBDA, respectively. The delay circuit 840 may have a delay time duration that is replicated from the propagation delay of the serializer 810 and the transmission circuit 820.

The reception circuit 830 may receive a first reference voltage VRH and a second reference voltage VRL to detect the voltage level of the node AP. The first reference voltage VRH may have a voltage level between a high boundary voltage level and middle voltage level of the node AP. The second reference voltage VRL may have a voltage level between the middle voltage level and low boundary voltage level of the node AP. When the first reception clock signal RICK is at a logic high level, the reception circuit 830 may sample the voltage level of the node AP by using the first and second reference voltages VRH and VRL, and may provide the sampled signal as the reception data DA2 based on the first delay data signal RID. When the second reception clock signal RQCK is at a logic high level, the reception circuit 830 may sample the voltage level of the node AP by using the first and second reference voltages VRH and VRL, and may provide the sampled signal as the reception data DA2 based on the second delay data signal RQD. When the third reception clock signal RICKB is at a logic high level, the reception circuit 830 may sample the voltage level of the node AP by using the first and second reference voltages VRH and VRL, and may provide the sampled signal as the reception data DA2 based on the third delay data signal RIBD. When the fourth reception clock signal ROCKB is at a logic high level, the reception circuit 830 may sample the voltage level of the node AP by using the first and second reference voltages VRH and VRL, and may provide the sampled signal as the reception data DA2 based on the fourth delay data signal RQBD.

The reception circuit 830 may include a sampling circuit 831 and a selection circuit 832. The sampling circuit 831 may generate a first detection signal DS1 and a second detection signal DS2 by comparing the voltage level of the node AP with each of the first and second reference voltages VRH and VRL in synchronization with the first reception clock signal RICK. The sampling circuit 831 may generate the results of the comparison between the voltage level of the node AP and the first reference voltage VRH as the first detection signal DS1, and may generate the results of the comparison between the voltage level of the node AP and the second reference voltage VRL as the second detection signal DS2. The sampling circuit 831 may generate a third detection signal DS3 and a fourth detection signal DS4 by comparing the voltage level of the node AP with each of the first and second reference voltages VRH and VRL in synchronization with the second reception clock signal RQCK. The sampling circuit 831 may generate the results of the comparison between the voltage level of the node AP and the first reference voltage VRH as the third detection signal DS3, and may generate the results of the comparison between the voltage level of the node AP and the second reference voltage VRL as the fourth detection signal DS4. The sampling circuit 831 may generate a fifth detection signal DS5 and a sixth detection signal DS6 by comparing the voltage level of the node AP with each of the first and second reference voltages VRH and VRL in synchronization with the third reception clock signal RICKB. The sampling circuit 831 may generate the results of the comparison between the voltage level of the node AP and the first reference voltage VRH as the fifth detection signal DS5, and may generate the results of the comparison between the voltage level of the node AP and the second reference voltage VRL as the sixth detection signal DS6. The sampling circuit 831 may generate a seventh detection signal DS7 and an eighth detection signal DS8 by comparing the voltage level of the node AP with each of the first and second reference voltages VRH and VRL in synchronization with the fourth reception clock signal ROCKB. The sampling circuit 831 may generate the results of the comparison between the voltage level of the node AP and the first reference voltage VRH as the seventh detection signal DS7, and may generate the results of the comparison between the voltage level of the node AP and the second reference voltage VRL as the eighth detection signal DS8.

The selection circuit 832 may output one of the first and second detection signals DS1 and DS2 as the reception data DA2 based on the first delay data signal RID, and may output one of the third and fourth detection signals DS3 and DS4 as the reception data DA2 based on the second delay data signal RQD. The selection circuit 832 may output one of the fifth and sixth detection signals DS5 and DS6 as the reception data DA2 based on the third delay data signal RIBD, and may output one of the seventh and eighth detection signals DS7 and DS8 as the reception data DA2 based on the fourth delay data signal RQBD. The selection circuit 832 may output the first detection signal DS1 as the reception data DA2 when the first delay data signal RID is at the first logic level, and may output the second detection signal DS2 as the reception data DA2 when the first delay data signal RID is at the second logic level. The selection circuit 832 may output the third detection signal DS3 as the reception data DA2 when the second delay data signal RQD is at the first logic level, and may output the fourth detection signal DS4 as the reception data DA2 when the second delay data signal RQD is at the second logic level. The selection circuit 832 may output the fifth detection signal DS5 as the reception data DA2 when the third delay data signal RIBD is at the first logic level, and may output the sixth detection signal DS6 as the reception data DA2 when the third delay data signal RIBD is at the second logic level. The selection circuit 832 may output the seventh detection signal DS7 as the reception data DA2 when the fourth delay data signal RQBD is at the first logic level, and may output the eighth detection signal DS8 as the reception data DA2 when the fourth delay data signal RQBD is at the second logic level.

The semiconductor device 800 may further include a shifting circuit 850. The shifting circuit 850 may align the first to fourth output data signals IDA, QDA, IBDA, and QBDA, and may provide the aligned data signal to the serializer 810. The shifting circuit 850 may receive the first to fourth transmission clock signals TICK, TQCK, TICKB, and TQCKB and the first to fourth output data signals IDA, QDA, IBDA, and QBDA. The shifting circuit 850 may align the first to fourth output data signals IDA, QDA, IBDA, and QBDA with the phases of the first to fourth transmission clock signals TICK, TQCK, TICKB, and TQCKB. The shifting circuit 850 may align the first to fourth output data signals IDA, QDA, IBDA, and QBDA to increase the operation margin of the serializer 810. The shifting circuit 850 may align the first to fourth output data signals IDA, QDA, IBDA, and QBDA by using a clock signal having a phase that is earlier than the phase of a clock signal with which the serializer 810 is synchronized. For example, the shifting circuit 850 may align the first output data signal IDA in synchronization with the fourth transmission clock signal TQCKB, and may align the second output data signal QDA in synchronization with the first transmission clock signal TICK. The shifting circuit 850 may align the third output data signal IBDA in synchronization with the second transmission clock signal TQCK, and may align the fourth output data signal QBDA in synchronization with the third transmission clock signal TICKB. The shifting circuit 850 may provide the serializer 810 with the first to fourth output data signals IDA, QDA, IBDA, and QBDA each aligned with the phases the fourth transmission clock signal TQCKB, the first transmission clock signal TICK, the second transmission clock signal TQCK, and the third transmission clock signal TCKB. A setup margin for enabling the serializer 810 to sample the first output data signal IDA can be sufficiently established or secured because the serializer 810 samples the first output data signal IDA that has been aligned with the phase of the fourth transmission clock signal TQCKB, in synchronization with the first transmission clock signal TICK. A setup margin for enabling the serializer 810 to sample the second output data signal QDA can be sufficiently established or secured because the serializer 810 samples the second output data signal QDA that has been aligned with the phase of the first transmission clock signal TICK, in synchronization with the second transmission clock signal TQCK. Likewise, a setup margin for enabling the serializer 810 to sample each of the third and fourth output data signals IBDA and QBDA can be sufficiently established or secured because the serializer 810 samples the third and fourth output data signals IBDA and QBDA that each have been aligned with the phase of each of the second and third transmission clock signals TQCK and TIBCK in synchronization with each of the third and fourth transmission clock signals TICKB and TQCKB.

The semiconductor device 800 may further include a parallelizer 860. The parallelizer 860 may receive the reception data DA2 from the reception circuit 830, and may generate first to fourth input data signals DID, DQD, DIBD, and DQBD by parallelizing the reception data DA2. The reception data DA2 may be serial data like the transmission data DA1. The parallelizer 860 may receive the first to fourth reception clock signals RICK, ROCK, RICKB, and ROCKB. The parallelizer 860 may generate the first to fourth input data signals DID, DQD, DIBD, and DQBD by parallelizing the reception data DA2 in synchronization with the first to fourth reception clock signals RICK, ROCK, RICKB, and ROCKB. For example, when the first reception clock signal RICK is at a logic high level, the parallelizer 860 may generate the first input data signal DID being at a logic level corresponding to the logic level of the reception data DA2. When the second reception clock signal ROCK is at a logic high level, the parallelizer 860 may generate the second input data signal DQD being at a logic level corresponding to the logic level of the reception data DA2. When the third reception clock signal RICKB is at a logic high level, the parallelizer 860 may generate the third input data signal DIBD being at a logic level corresponding to the logic level of the reception data DA2. When the fourth reception clock signal ROCKB is at a logic high level, the parallelizer 860 may generate the fourth input data signal DQBD being at a logic level corresponding to the logic level of the reception data DA2.

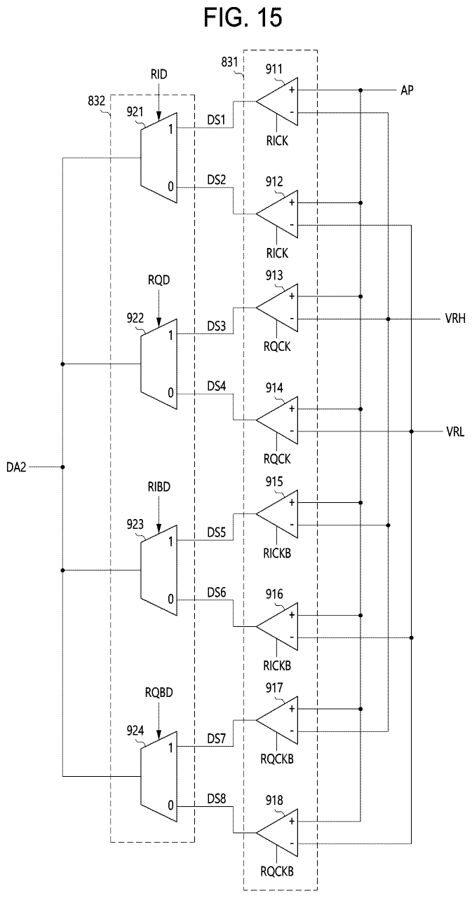

FIG. 15 is a diagram illustrating a configuration and connection relation of the sampling circuit 831 and the selection circuit 832 illustrated in FIG. 14. Referring to FIG. 15, the sampling circuit 831 may include a first comparator 911, a second comparator 912, a third comparator 913, a fourth comparator 914, a fifth comparator 915, a sixth comparator 916, a seventh comparator 917, and an eighth comparator 918. The first and second comparators 911 and 912 may receive the first reception clock signal RICK, and may be activated when the first reception clock signal RICK is at a logic high level. The third and fourth comparators 913 and 914 may receive the second reception clock signal ROCK, and may be activated when the second reception clock signal ROCK is at a logic high level. The fifth and sixth comparators 915 and 916 may receive the third reception clock signal RICKB, and may be activated when the third reception clock signal RICKB is at a logic high level. The seventh and eighth comparators 917 and 918 may receive the fourth reception clock signal RQCKB, and may be activated when the fourth reception clock signal RQCKB is at a logic high level. The first comparator 911 may receive the voltage level of the node AP and the first reference voltage VRH, and may generate the first detection signal DS1 by comparing the voltage level of the node AP and the first reference voltage VRH. The second comparator 912 may receive the voltage level of the node AP and the second reference voltage VRL, and may generate the second detection signal DS2 by comparing the voltage level of the node AP and the second reference voltage VRL. The third comparator 913 may receive the voltage level of the node AP and the first reference voltage VRH, and may generate the third detection signal DS3 by comparing the voltage level of the node AP and the first reference voltage VRH. The fourth comparator 914 may receive the voltage level of the node AP and the second reference voltage VRL, and may generate the fourth detection signal DS4 by comparing the voltage level of the node AP and the second reference voltage VRL. The fifth comparator 915 may receive the voltage level of the node AP and the first reference voltage VRH, and may generate the fifth detection signal DS5 by comparing the voltage level of the node AP and the first reference voltage VRH. The sixth comparator 916 may receive the voltage level of the node AP and the second reference voltage VRL, and may generate the sixth detection signal DS6 by comparing the voltage level of the node AP and the second reference voltage VRL. The seventh comparator 917 may receive the voltage level of the node AP and the first reference voltage VRH, and may generate the seventh detection signal DS7 by comparing the voltage level of the node AP and the first reference voltage VRH. The eighth comparator 918 may receive the voltage level of the node AP and the second reference voltage VRL, and may generate the eighth detection signal DS8 by comparing the voltage level of the node AP and the second reference voltage VRL.

The selection circuit 832 may include a first multiplexer 921, a second multiplexer 922, a third multiplexer 923, and a fourth multiplexer 924. The first multiplexer 921 may receive the first delay data signal RID, the first detection signal DS1, and the second detection signal DS2. The first multiplexer 921 may output the first detection signal DS1 as the reception data DA2 when the first delay data signal RID is at a logic high level. The first multiplexer 921 may output the second detection signal DS2 as the reception data DA2 when the first delay data signal RID is at a logic low level. The second multiplexer 922 may receive the second delay data signal RQD, the third detection signal DS3, and the fourth detection signal DS4. The second multiplexer 922 may output the third detection signal DS3 as the reception data DA2 when the second delay data signal RQD is at a logic high level. The second multiplexer 922 may output the fourth detection signal DS4 as the reception data DA2 when the second delay data signal RQD is at a logic low level. The third multiplexer 923 may receive the third delay data signal RIBD, the fifth detection signal DS5, and the sixth detection signal DS6. The third multiplexer 923 may output the fifth detection signal DS5 as the reception data DA2 when the third delay data signal RIBD is at a logic high level. The third multiplexer 923 may output the sixth detection signal DS6 as the reception data DA2 when the third delay data signal RIBD is at a logic low level. The fourth multiplexer 924 may receive the fourth delay data signal RQBD, the seventh detection signal DS7, and the eighth detection signal DS8. The fourth multiplexer 924 may output the seventh detection signal DS7 as the reception data DA2 when the fourth delay data signal RQBD is at a logic high level. The fourth multiplexer 924 may output the eighth detection signal DS8 as the reception data DA2 when the fourth delay data signal RQBD is at a logic low level.

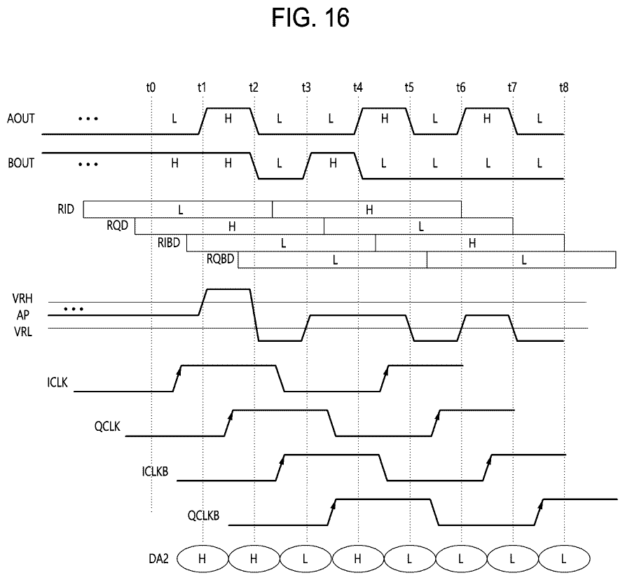

FIG. 16 is a timing diagram illustrating an operation of the semiconductor device 800 according to an embodiment. The operation of the semiconductor device 800 is described as follows with reference to FIGS. 14 to 16. The output voltage AOUT that is generated by the transmission circuit 820 and the output voltage BOUT that is transmitted by the other semiconductor device through the signal transmission line 801 may be superposed at the node AP. The reception circuit 830 may detect the voltage level of the node AP based on the first to fourth output data signals IDA, QDA, IBDA, and QBDA and not the transmission data DA1. When the first reception clock signal RICK is at a logic high level, the reception circuit 830 may generate the first and second detection signals DS1 and DS2 by comparing the voltage level of the node AP with each of the first and second reference voltages VRH and VRL. The reception circuit 830 may output one of the first and second detection signals DS1 and DS2 as the reception data DA2 based on the logic level of the first delay data signal RID. When the second reception clock signal RQCK is at a logic high level, the reception circuit 830 may generate the third and fourth detection signals DS3 and DS4 by comparing the voltage level of the node AP with each of the first and second reference voltages VRH and VRL. The reception circuit 830 may output one of the third and fourth detection signals DS3 and DS4 as the reception data DA2 based on the logic level of the second delay data signal RQD. When the third reception clock signal RICKB is at a logic high level, the reception circuit 830 may generate the fifth and sixth detection signals DS5 and DS6 by comparing the voltage level of the node AP with each of the first and second reference voltages VRH and VRL. The reception circuit 830 may output one of the fifth and sixth detection signals DS5 and DS6 as the reception data DA2 based on the logic level of the third delay data signal RIBD. When the fourth reception clock signal ROCKB is at a logic high level, the reception circuit 830 may generate the seventh and eighth detection signals DS7 and DS8 by comparing the voltage level of the node AP with each of the first and second reference voltages VRH and VRL. The reception circuit 830 may output one of the seventh and eighth detection signals DS7 and DS8 as the reception data DA2 based on the logic level of the fourth delay data signal RQBD. Accordingly, a margin in which the reception data DA2 may be sampled based on the voltage level of the node AP can be increased by one cycle of each of the first to fourth reception clock signals RICK, ROCK, RICKB, and ROCKB.

In an interval between times to and t1, the first delay data signal RID is at a logic low level, the reception circuit 830 outputs the second detection signal DS2 as a first bit of the reception data DA2, and the first bit of the reception data DA2 may be at a logic high level. In an interval between times t1 and t2, the second delay data signal RQD is at a logic high level, the reception circuit 830 outputs the third detection signal DS3 as a second bit of the reception data DA2, and the second bit of the reception data DA2 may be at a logic high level. In an interval between times t2 and t3, the third delay data signal RIBD is at a logic low level, the reception circuit 830 outputs the fifth detection signal DS5 as a third bit of the reception data DA2, and the third bit of the reception data DA2 may be at a logic low level. In an interval between times t3 and t4, the fourth delay data signal RQBD is at a logic low level, the reception circuit 830 outputs the eighth detection signal DS8 as a fourth bit of the reception data DA2, and the fourth bit of the reception data DA2 may be at a logic high level. In an interval between times t4 and t5, the first delay data signal RID is at a logic high level, the reception circuit 830 outputs the first detection signal DS1 as a fifth bit of the reception data DA2, and the fifth bit of the reception data DA2 may be at a logic low level. In an interval between times t5 and t6, the second delay data signal RQD is at a logic low level, the reception circuit 830 outputs the fourth detection signal DS4 as a sixth bit of the reception data DA2, and the sixth bit of the reception data DA2 may be at a logic low level. In an interval between times t6 and t7, the third delay data signal RIBD is at a logic high level, the reception circuit 830 outputs the fifth detection signal DS5 as a seventh bit of the reception data DA2, and the seventh bit of the reception data DA2 may be at a logic low level. In an interval between times t7 and t8, the fourth delay data signal RQBD is at a logic low level, the reception circuit 830 outputs the eighth detection signal DS8 as an eighth bit of the reception data DA2, and the eighth bit of the reception data DA2 may be at a logic low level. Accordingly, each of the first to eighth bits of the reception data DA2 may have a voltage level corresponding to the output voltage BOUT that is transmitted by the other semiconductor device through the signal transmission line 801.

Those skilled in the art to which the present technology pertains will understand that the aforementioned embodiments are illustrative from all aspects not being limitative because the present technology may be implemented in various other forms without departing from the technical spirit or essential characteristics of the present technology. The scope of the present technology is defined by the appended claims rather than by the detailed description, and all modifications or variations derived from the meanings and scope of the claims and equivalents thereof should be understood as being included in the scope of the present technology.

What is claimed is:

1. A semiconductor device comprising:
a serializer configured to generate transmission data by serializing a first output data signal and a second output data signal based on a first transmission clock signal and a second transmission clock signal;
a transmission circuit configured to drive, based on the transmission data, a node electrically coupled to a signal transmission line; and
a reception circuit configured to generate, based on a first reception clock signal, a second reception clock signal, the first output data signal, and the second output data signal, reception data by detecting a voltage level of the node.

2. The semiconductor device of claim 1, wherein the serializer is configured to output the first output data signal as the transmission data in synchronization with the first transmission clock signal, and configured to output the second output data signal as the transmission data in synchronization with the second transmission clock signal.

3. The semiconductor device of claim 2, further comprising a shifting circuit configured to align the first output data signal in synchronization with the second transmission clock signal and configured to align the second output data signal in synchronization with the first transmission clock signal,
wherein the serializer is configured to receive the first and second output data signals that are aligned by the shifting circuit.

4. The semiconductor device of claim 1, further comprising a delay circuit configured to generate a first delay data signal and a second delay data signal by delaying the first output data signal and the second output data signal.

5. The semiconductor device of claim 4, wherein the delay circuit has a delay time duration that is replicated from the propagation delay of the serializer and the transmission circuit.

6. The semiconductor device of claim 4, wherein the reception circuit comprises:
a sampling circuit configured to generate a first detection signal and a second detection signal by comparing the voltage level of the node with a first reference voltage and a second reference voltage in synchronization with the first reception clock signal and configured to generate a third detection signal and a fourth detection signal by comparing the voltage level of the node with the first reference voltage and the second reference voltage in synchronization with the second reception clock signal; and
a selection circuit configured to output one of the first and second detection signals as the reception data based on the first delay data signal and configured to output one of the third and fourth detection signals as the reception data based on the second delay data signal.

7. The semiconductor device of claim 6, wherein the sampling circuit comprises:
a first comparator configured to generate the first detection signal by comparing the voltage level of the node with the first reference voltage in synchronization with the first reception clock signal;
a second comparator configured to generate the second detection signal by comparing the voltage level of the node with the second reference voltage in synchronization with the first reception clock signal;
a third comparator configured to generate the third detection signal by comparing the voltage level of the node with the first reference voltage in synchronization with the second reception clock signal; and
a fourth comparator configured to generate the fourth detection signal by comparing the voltage level of the node with the second reference voltage in synchronization with the second reception clock signal.

8. The semiconductor device of claim 6, wherein the sampling circuit is configured to:
change the voltage level of the node that is input to the first comparator based on the third detection signal,
change the voltage level of the node that is input to the second comparator based on the fourth detection signal,
change the voltage level of the node that is input to the third comparator based on the first detection signal, and
change the voltage level of the node that is input to the fourth comparator based on the second detection signal.

9. The semiconductor device of claim 6, further comprising a feed forward equalization circuit configured to generate a feed forward control signal based on the transmission data,
wherein the sampling circuit is configured to sum up the feed forward control signal and the voltage level of the node and configured to compare the summed signal with the first and second reference voltages.

10. The semiconductor device of claim 6, wherein the selection circuit comprises:
a first multiplexer configured to output the first detection signal as the reception data when the first delay data signal is at a first logic level and to output the second detection signal as the reception data when the first delay data signal is at a second logic level; and
a second multiplexer configured to output the third detection signal as the reception data when the second delay data signal is at the first logic level and to output the fourth detection signal as the reception data when the second delay data signal is at the second logic level.

11. The semiconductor device of claim 4, wherein the reception circuit comprises:
a first equalization circuit configured to generate a first equalization signal by equalizing the voltage level of the node based on a voltage level of the first delay data signal;
a second equalization circuit configured to generate a second equalization signal by equalizing the voltage level of the node based on a voltage level of the second delay data signal;
a first comparator configured to generate the reception data by comparing the first equalization signal with a third reference voltage in synchronization with the first reception clock signal; and
a second comparator configured to generate the reception data by comparing the second equalization signal with the third reference voltage in synchronization with the second reception clock signal.

12. The semiconductor device of claim 1, further comprising a delay setting circuit that is electrically coupled between the node and the signal transmission line,
wherein a delay time duration of the delay setting circuit is set based on the voltage level of the node.

13. The semiconductor device of claim 12,
wherein the delay setting circuit is configured to set a delay time duration of the delay setting circuit so that a sum of a propagation delay time duration of the signal transmission line and the delay time duration of the delay setting circuit corresponds to a multiple of a unit time, and
the unit time corresponds to duration of the transmission data.

14. The semiconductor device of claim 12, wherein the delay setting circuit comprises:
a voltage detection circuit configured to generate a voltage detection signal by comparing the voltage level of the node with at least one of a first reference voltage and a second reference voltage;
a delay control circuit configured to generate a delay control signal based on the voltage detection signal; and
a variable delay circuit that is electrically coupled between the node and the signal transmission line and that has a delay time duration changed based on the delay control signal.

15. The semiconductor device of claim 1, wherein:
each of the first and second reception clock signals has a cycle identical with the first and second transmission clock signals, and
each of the first and second reception clock signals has a phase that is later than a phase of each of the first and second transmission clock signals by a quarter (¼) of a cycle.

16. The semiconductor device of claim 1, wherein:
the first and second output data signals are parallel data, and
the transmission data is serial data.

17. The semiconductor device of claim 1, wherein each of the first and second output data signals has a longer duration than the transmission data.

18. The semiconductor device of claim 1, further comprising a parallelizer configured to generate a first input data signal and a second input data signal by parallelizing the reception data based on the first and second reception clock signals.

19. A semiconductor device comprising:
a serializer configured to generate transmission data by serializing a first output data signal, a second output data signal, a third output data signal, and a fourth output data signal, based on a first transmission clock signal, a second transmission clock signal, a third transmission clock signal, and a fourth transmission clock signal having different phases;
a delay circuit configured to generate a first delay data signal, a second delay data signal, a third delay data signal, and a fourth delay data signal by delaying the first, second, third, and fourth output data signals, respectively;
a transmission circuit configured to drive, based on the transmission data, a node that is electrically coupled to a signal transmission line; and
a reception circuit configured to generate reception data by detecting a voltage level of the node, based on a first reception clock signal, a second reception clock signal, a third reception clock signal, and a fourth reception clock signal, and the first, second, third, and fourth delay data signals having different phases.

20. The semiconductor device of claim 19, wherein the serializer is configured to:
output the first output data signal as the transmission data in synchronization with the first transmission clock signal,
output the second output data signal as the transmission data in synchronization with the second transmission clock signal,
output the third output data signal as the transmission data in synchronization with the third transmission clock signal, and
output the fourth output data signal as the transmission data in synchronization with the fourth transmission clock signal.

21. The semiconductor device of claim 19, further comprising a shifting circuit configured to:
align the first output data signal in synchronization with the fourth transmission clock signal,
align the second output data signal in synchronization with the first transmission clock signal,
align the third output data signal in synchronization with the second transmission clock signal, and
align the fourth output data signal in synchronization with the third transmission clock signal,
wherein the serializer and the delay circuit are configured to receive the first, second, third, and fourth output data signals aligned by the shifting circuit.

22. The semiconductor device of claim 19, wherein the delay circuit has a delay time duration that is replicated from the propagation delay of the serializer and the transmission circuit.

23. The semiconductor device of claim 19, wherein:
the first, second, third, and fourth output data signals are parallel data, and
the transmission data is serial data.

24. The semiconductor device of claim 19, wherein duration of each of the first, second, third, and fourth output data signals is four times the duration of the transmission data.

25. The semiconductor device of claim 19, wherein the reception circuit comprises:
a sampling circuit configured to:
generate a first detection signal and a second detection signal by comparing the voltage level of the node with a first reference voltage and a second reference voltage in synchronization with the first reception clock signal,
generate a third detection signal and a fourth detection signal by comparing the voltage level of the node with the first reference voltage and the second reference voltage in synchronization with the second reception clock signal,
generate a fifth detection signal and a sixth detection signal by comparing the voltage level of the node with the first reference voltage and the second reference voltage in synchronization with the third reception clock signal, and
generate a seventh detection signal and an eighth detection signal by comparing the voltage level of the node with the first reference voltage and the second reference voltage in synchronization with the fourth reception clock signal; and
a selection circuit configured to:
output one of the first and second detection signals as the reception data based on the first delay data signal,
output one of the third and fourth detection signals as the reception data based on the second delay data signal,
output one of the fifth and sixth detection signals as the reception data based on the third delay data signal, and
output one of the seventh and eighth detection signals as the reception data based on the fourth delay data signal.

26. The semiconductor device of claim 19, wherein:
each of the first, second, third, and fourth reception clock signals has a cycle identical with each of the first to fourth transmission clock signals, and
each of the first, second, third, and fourth reception clock signals has a phase that is later than a phase of each of the first, second, third, and fourth transmission clock signals by an eighth (⅛) of a cycle.

27. The semiconductor device of claim 19, further comprising a parallelizer configured to generate a first input data signal, a second input data signal, a third input data signal, and a fourth input data signal by parallelizing the reception data based on the first, second, third, and fourth reception clock signals.
